(19) United States
(12) Patent Application Publication
(10) Pub. No.: US 2026/0231619 A1
(43) Pub. Date: Aug. 6, 2026

(54) DISPLAY DEVICE, ELECTRONIC DEVICE AND METHOD FOR FABRICATING THE SAME

(71) Applicant: Samsung Display Co., LTD., Yongin-si (KR)

(72) Inventors: Jong Hee PARK, Yongin-si (KR); Su Kyoung YANG, Yongin-si (KR); Joon Yong PARK, Yongin-si (KR); Hee Jun YANG, Yongin-si (KR)

(21) Appl. No.: 19/319,060

(22) Filed: Sep. 4, 2025

(30) Foreign Application Priority Data
Jan. 31, 2025 (KR) 10-2025-0012253

(51) Int. Cl. H10K 59/122; H10H 29/01; H10H 29/37; H10H 29/49; H10H 29/80; H10K 59/12; H10K 59/131; H10K 59/80

(52) U.S. Cl. CPC H10K 59/122; H10H 29/012; H10H 29/37; H10H 29/49; H10H 29/8321; H10K 59/1201; H10K 59/1315; H10K 59/80521

(57) ABSTRACT

A display device includes a substrate including a light emitting area and a non-light emitting area; a bank structure positioned on the light emitting area of the substrate, where the bank structure includes a first bank layer, a second bank layer, and a third bank layer which define an overhang structure; and a light emitting element positioned on the bank structure and including an anode electrode, a light emitting layer, and a cathode electrode, where the third bank layer includes: a first upper conductive layer positioned on the second bank layer and including a first tip protruding further than a side surface of the second bank layer; and a second upper conductive layer positioned on the first upper conductive layer and including a second tip overlapping the first tip, and an undercut is defined between the first tip and the second tip.

This application claims priority to Korean Patent Application No. 10-2025-0012253,

filed on Jan. 31, 2025, and all the benefits accruing therefrom under 35 U.S.C. § 119, the content of which in its entirety is herein incorporated by reference.

### BACKGROUND

### 1. Field

The present disclosure relates to a display device, an electronic device using the display device, and a method for fabricating the display device.

### 2. Description of the Related Art

As an information society develops, the demand for a display device for displaying an image is increasing in various forms. For example, the display device has been applied to various electronic devices such as smartphones, digital cameras, laptop computers, navigation devices, and smart televisions. The display device may be a flat panel display device such as a liquid crystal display device, a field emission display device, or an organic light emitting display device. Among the flat panel display devices, the light emitting display device may include a light emitting element in which each of the pixels of a display panel may emit light by itself, thereby displaying an image without using a backlight unit for providing the light to the display panel.

### SUMMARY

Embodiments of the present disclosure provide a display device capable of providing a high resolution image, an electronic device using the display device, and a method for fabricating the display device.

Embodiments of the present disclosure are to reduce electrical resistance of a display device by increasing a contact area between a bank structure and a cathode electrode in a high-resolution display device.

However, embodiments of the present disclosure are not restricted to those set forth herein. The above and other embodiments of the present disclosure will become more apparent to one of ordinary skill in the art to which the present disclosure pertains by referencing the detailed description of the present disclosure given below.

Details of other embodiments are included in the detailed description and drawings.

In an embodiment of the disclosure, a display device includes: a substrate including a light emitting area and a non-light emitting area; a bank structure positioned on the light emitting area of the substrate, where the bank structure includes a first bank layer, a second bank layer, and a third bank layer which define an overhang structure; and a light emitting element positioned on the bank structure and including an anode electrode, a light emitting layer, and a cathode electrode, where the third bank layer includes: a first upper conductive layer positioned on the second bank layer and including a first tip protruding further than a side surface of the second bank layer; and a second upper conductive layer positioned on the first upper conductive layer and including a second tip overlapping the first tip, and an undercut is defined between the first tip and the second tip.

In an embodiment, the first tip may include a first surface facing the second bank layer; a second surface opposite to the first surface; and a first inclined surface connecting the first surface and the second surface, and a first inclined angle formed by the first surface and the first inclined surface may be an acute angle.

In an embodiment, the second tip may include a third surface facing the first upper conductive layer; a fourth surface opposite to the third surface; and a second inclined surface connecting the third surface and the fourth surface, a second inclined angle formed by the third surface and the second inclined surface may be an acute angle, and the second inclined angle may be greater than the first inclined angle.

In an embodiment, an undercut may be defined between the first inclined surface and the second tip, and the cathode electrode may be in contact with and cover the first tip and the second tip.

In an embodiment, the second bank layer, the first upper conductive layer, and the second upper conductive layer may include different metal materials from each other.

In an embodiment, the first upper conductive layer may include a transparent conductive oxide including tin, and a content of tin in the first upper conductive layer is about 18% or more and about 30% or less.

In an embodiment, the second bank layer may include aluminum, and the second upper conductive layer includes titanium.

In an embodiment, the display device may further include a first element insulating layer positioned between the bank structure and the anode electrode; and a second element insulating layer covering an edge of the anode electrode and in contact with the first element insulating layer, where a light emitting opening is defined in the second element insulating layer, and the first element insulating layer and the second element insulating layer overlap the first tip and the second tip.

In an embodiment, the light emitting layer may entirely cover the second element insulating layer, the light emitting layer overlaps the first tip and the second tip in a direction perpendicular to the substrate, and the light emitting layer may not be in contact with the first tip of the first upper conductive layer.

In an embodiment, in a plan view, the third bank layer may have a shape of a conductive pattern positioned to surround the light emitting opening.

In an embodiment, the third bank layer may further include a third upper conductive layer positioned on the second upper conductive layer and including a third tip overlapping the first tip and the second tip; and a fourth upper conductive layer positioned on the third upper conductive layer and including a fourth tip overlapping the first tip, the second tip, and the third tip, the first upper conductive layer and the third upper conductive layer may include a same material as each other, and the second upper conductive layer and the fourth upper conductive layer may include a same material as each other.

In an embodiment of the disclosure, a method for fabricating a display device, the method includes forming a first bank layer, a second bank layer, and a third bank layer of a bank structure on a substrate; forming a first tip and a second tip of the third bank layer by performing different etching processes, respectively; and forming a light emitting element and an element inorganic layer on the bank structure.

In an embodiment, the third bank layer may include a first upper conductive layer and a second upper conductive layer including different materials from each other, the first upper conductive layer may include a transparent conductive oxide including tin, and the first upper conductive layer may have a first tip which protrudes further than a side surface of the second bank layer formed by performing a wet etching process.

In an embodiment, the second upper conductive layer may include titanium, and the second upper conductive layer may have a second tip which protrudes further than the side surface of the second bank layer formed by performing a dry etching process.

In an embodiment of the disclosure, an electronic device includes a display device including a substrate including a light emitting area and a non-light emitting area; and at least one selected from a processor, a memory, and a power module connected to the display device, where the display device includes: a bank structure positioned on the light emitting area of the substrate, where the bank structure includes a first bank layer, a second bank layer, and a third bank layer which define an overhang structure; and a light emitting element positioned on the bank structure and including an anode electrode, a light emitting layer, and a cathode electrode, the third bank layer includes: a first upper conductive layer positioned on the second bank layer and including a first tip protruding further than a side surface of the second bank layer; and a second upper conductive layer positioned on the first upper conductive layer and including a second tip overlapping the first tip, and an undercut is define between the first tip and the second tip.

According to embodiments, the display device capable of providing the high-resolution image and reducing the electrical resistance of the display device by increasing the contact area between the bank structure and the cathode electrode, the electronic device using the display device, and the method for fabricating the display device may be provided.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other features of embodiments of the present disclosure will become more apparent by describing in detail embodiments thereof with reference to the attached drawings, in which:

FIG. 1 is a perspective view illustrating a display device according to an embodiment;

FIG. 2 is a cross-sectional view illustrating the display device according to an embodiment;

FIG. 3 is a plan view illustrating a display layer of FIG. 2;

FIG. 4 is a plan view illustrating an arrangement of a plurality of pixels disposed in a display area of FIG. 3;

FIG. 5 is a cross-sectional view illustrating an example of the display layer taken along line X1-X1′ of FIG. 4;

FIG. 6 is an enlarged cross-sectional view of a display element layer overlapping a first light emitting area in FIG. 5;

FIG. 7 is an enlarged cross-sectional view of area ‘A’ in FIG. 6;

FIG. 8 is a cross-sectional view illustrating an example of the display layer taken along line X3-X3′ of FIG. 4;

FIG. 9 is a cross-sectional view illustrating an example of the display layer taken along line X5-X5′ of FIG. 4 according to another embodiment;

FIG. 10 is an enlarged cross-sectional view of area ‘C’ of FIG. 9;

FIG. 11 is a flowchart illustrating an embodiment of a method for fabricating the display element layer of FIG. 5;

FIG. 12 is a cross-sectional view for describing process S100 of FIG. 11;

FIGS. 13 to 17 are cross-sectional views for describing process S200 of FIG. 11;

FIGS. 18 to 21 are cross-sectional views for describing process S300 of FIG. 11;

FIG. 22 is a block diagram of an electronic device according to an embodiment; and

FIG. 23 illustrates schematic diagrams of electronic devices according to various embodiments.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element or layer is referred to as being “on” another element or layer, the element or layer can be directly on another element or layer or intervening elements or layers may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,“ unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Features of various embodiments of the present disclosure may be partially or entirely coupled to or combined with each other, and may be inter-operated and driven in technically various ways. The embodiments may be implemented independently from each other, or may be implemented together in a co-dependent relationship.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure will be described in detail with reference to the accompanying drawings.

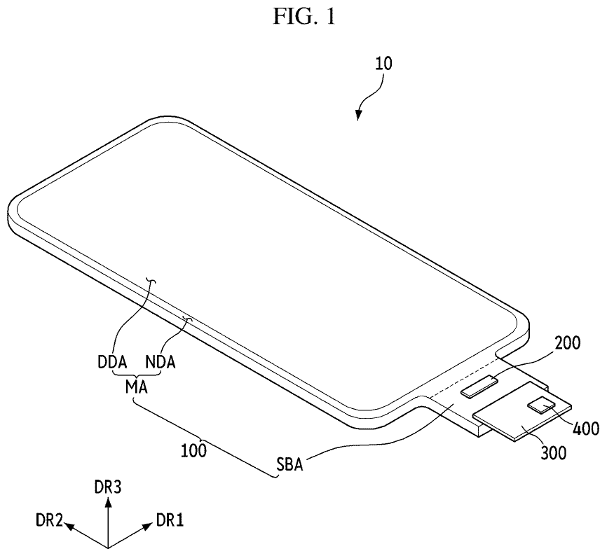

FIG. 1 is a perspective view illustrating a display device according to an embodiment.

Referring to FIG. 1, an embodiment of a display device 10 may be applied to portable electronic devices such as a mobile phone, a smartphone, a tablet personal computer (PC), a mobile communication terminal, an electronic notebook, an electronic book, a portable multimedia player (PMP), navigation, and an ultra mobile PC (UMPC). In an embodiment, for example, the display device 10 may be applied to a display unit of a television, a laptop computer, a monitor, a billboard, or the Internet of Things (IoT). In another embodiment, for example, the display device 10 may be applied to a wearable device such as a smart watch, a watch phone, a glasses-type display, and a head mounted display (HMD).

In an embodiment, the display device 10 may be formed in a planar shape similar to a quadrangle. In an embodiment, for example, the display device 10 may have a planar shape similar to a quadrangle having a short side in a first direction DR1 and a long side in a second direction DR2. A corner where the short side in the first direction DR1 and the long side in the second direction DR2 meet may be rounded to have a predetermined curvature or may be formed at a right angle. The planar shape of the display device 10 is not limited to the quadrangle, and may be formed similarly to other polygons, circles, or ovals. Here, a third direction DR3 may be direction perpendicular to the first direction DR1 and the second direction DR3, and may be a thickness direction of the display device 10.

In an embodiment, the display device 10 may include a display panel 100, a display driver 200, a circuit board 300, and a touch driver 400.

The display panel 100 may include a main area MA and a sub-area SBA. The main area MA may include a display area DDA including pixels displaying an image, and a non-display area NDA positioned around the display area DDA.

The display area DDA may emit light from a plurality of light emitting areas or a plurality of openings to be described later. In an embodiment, for example, the display panel 100 may include a pixel circuit including switching elements, an element insulating layer defining the light emitting areas or the openings, and a self-light emitting element. In an embodiment, for example, the self-light emitting element may include, but is not limited to, an organic light emitting diode (LED) including an organic light emitting layer, a quantum dot LED including a quantum dot light emitting layer, an inorganic LED including an inorganic semiconductor, or a micro LED. In the drawings, for convenience of illustration, embodiments where the self-light emitting element is an organic light emitting diode are mainly shown.

The non-display area NDA may be an area outside the display area DDA. The non-display area NDA may be defined as an edge area of the main area MA of the display panel 100.

The sub-area SBA may be an area extending from one side of the main area MA. The sub-area SBA may include a flexible material that may be bent, folded, rolled, or the like. In an embodiment, for example, when the sub-area SBA is bent, the sub-area SBA may overlap the main area MA in a thickness direction (e.g., the third direction DR3). The sub-area SBA may include the display driver 200 and a pad portion connected to the circuit board 300. In another embodiment, the sub-area SBA may be omitted, and the display driver 200 and the pad portion may be positioned in the non-display area NDA.

The display driver 200 may output signals and voltages for driving the display panel 100. The display driver 200 may be formed as an integrated circuit (IC) and mounted on the display panel 100 by a chip on glass (COG) method, a chip on plastic (COP) method, or an ultrasonic bonding method. In an embodiment, for example, the display driver 200 may be positioned in the sub-area SBA, and may overlap the main area MA in the thickness direction by bending of the sub-area SBA. In another embodiment, for example, the display driver 200 may be mounted on the circuit board 300.

The circuit board 300 may be attached onto the pad portion of the display panel 100 using an anisotropic conductive film (ACF). The circuit board 300 may be a flexible film such as a flexible printed circuit board, a printed circuit board, or a chip on film.

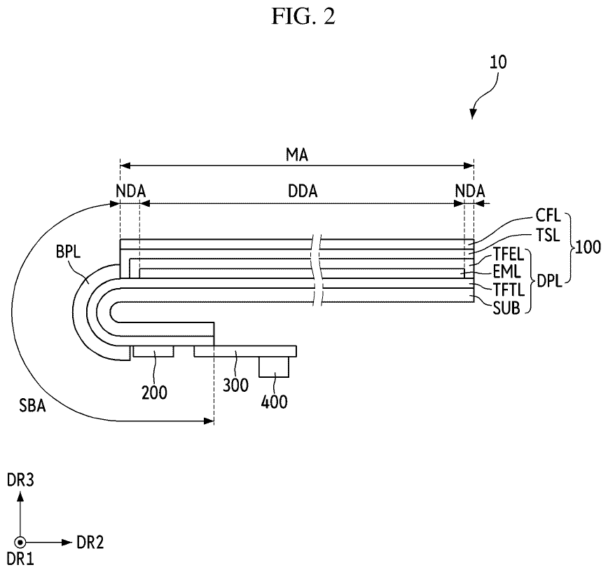

The touch driver 400 may be mounted on the circuit board 300. The touch driver 400 may be connected to a touch sensor layer (‘TSL’ in FIG. 2) for sensing and driving a touch.

FIG. 2 is a cross-sectional view illustrating the display device according to an embodiment.

Referring to FIG. 2, an embodiment of the display panel 100 may include a display layer DPL, a touch sensor layer TSL, and a color filter layer CFL. The display layer DPL may include a substrate SUB, a transistor layer TFTL, a display element layer EML, and a thin film encapsulation layer TFEL.

The substrate SUB may be a base substrate or a base member. The substrate SUB may be a flexible substrate that may be bent, folded, rolled, or the like. In an embodiment, for example, the substrate SUB may include a polymer resin such as polyimide PI, but is not limited thereto. In another embodiment, the substrate SUB may include a glass material or a metal material.

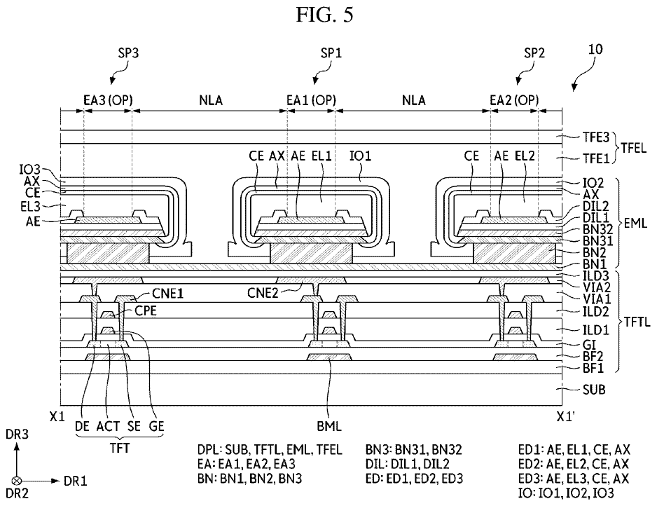

The transistor layer TFTL may be positioned on the substrate SUB. The transistor layer TFTL may be positioned in a portion overlapping the display area DDA, the non-display area NDA, and the sub-area SBA. The transistor layer TFTL may include a plurality of transistors (‘TFT’ in FIG. 5).

The display element layer EML may be positioned on the transistor layer TFTL. The display element layer EML may be positioned in a portion overlapping the display area DDA. The display element layer EML may include, but is not limited to, at least one selected from an organic light emitting diode (LED) including an organic light emitting layer, a quantum dot LED including a quantum dot light emitting layer, an inorganic LED including an inorganic semiconductor, and a micro LED.

The thin film encapsulation layer TFEL may be positioned on the display element layer EML. The thin film encapsulation layer TFEL may be positioned in a portion overlapping the display area DDA and the non-display area NDA. The thin film encapsulation layer TFEL may cover upper and side surfaces of the display element layer EML, and may protect the display element layer EML from oxygen and moisture from the outside. The thin film encapsulation layer TFEL may include at least one inorganic film and at least one organic film for encapsulating the display element layer EML. In some embodiments, the thin film encapsulation layer TFEL may be omitted.

The touch sensor layer TSL may be positioned on the thin film encapsulation layer TFEL. The touch sensor layer TSL may be positioned in a portion overlapping the display area DDA and the non-display area NDA. The touch sensor layer TSL may sense a user's touch in a mutual capacitance method or a self-capacitance method. In some embodiments, the touch sensor layer TSL may be omitted.

The color filter layer CFL may be positioned on the touch sensor layer TSL. The color filter layer CFL may be positioned in a portion overlapping the display area DDA and the non-display area NDA. The color filter layer CFL may absorb a portion of light introduced from the outside of the display device 10 to reduce reflected light caused by external light. Therefore, the color filter layer CFL may effectively prevent color distortion caused by reflection of external light.

In an embodiment where the color filter layer CFL is directly disposed on the touch sensor layer TSL, the display device 10 may not include a separate substrate for the color filter layer CFL. Therefore, the display device 10 may have a relatively small thickness. In some embodiments, the color filter layer CFL may also be omitted.

In an embodiment, as illustrated in FIG. 2, a portion of the display panel 100 overlapping the sub-area SBA may be bent. In a state where a portion of the display panel 100 is bent, the display driver 200, circuit board 300, and the touch driver 400 may overlap the main area MA in the third direction DR3.

In a state where a portion of the display panel 100 is bent, a bending protection layer BPL may protect a lower structure overlapping the sub-area SBA from bending stress.

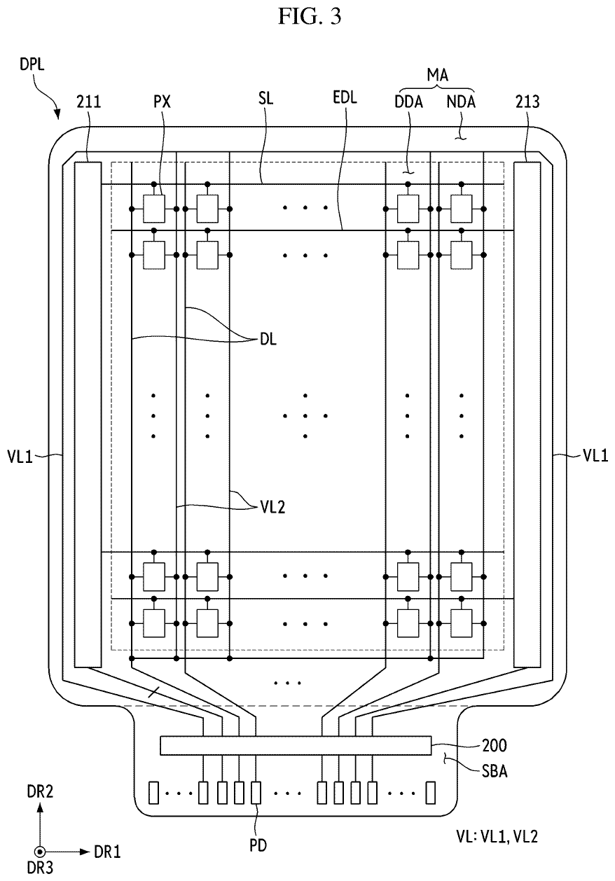

FIG. 3 is a plan view illustrating a display layer of FIG. 2.

Referring to FIG. 3, an embodiment of the display layer DPL may include a plurality of pixels PX in a portion overlapping the display area DDA, and a plurality of power lines VL, a plurality of scan lines SL, a plurality of emission control lines EDL, and a plurality of data lines DL that are connected to the plurality of pixels PX.

Each of the plurality of scan lines SL may extend in the first direction DR1 and may be spaced apart from each other in the second direction DR2 intersecting the first direction DR1. The scan lines SL may be arranged along the second direction DR2. The scan lines SL may sequentially supply a scan signal to the plurality of pixels PX.

Each of the emission control lines EDL may extend in the first direction DR1 and may be spaced apart from each other in the second direction DR2. The emission control lines EDL may be arranged along the second direction DR2. The emission control lines EDL may sequentially supply a light emitting signal to the plurality of pixels PX.

The data lines DL may extend in the second direction DR2 and may be spaced apart from each other in the first direction DR1. The data lines DL may be arranged along the first direction DR1. The data lines DL may supply a data voltage to the plurality of pixels PX. The data voltage may determine luminance of each of the plurality of pixels PX.

The power line VL may include a main power line VL1 and a sub-power line VL2. At least one selected from a first power voltage (high potential voltage) or a second power voltage (low potential voltage) may be transmitted to the sub-power line VL2 through the main power line VL1 overlapping the non-display area NDA. Hereinafter, the main power line VL1 and the sub-power line VL2 may be collectively referred to as the power line VL.

The non-display area NDA may surround the display area DDA. The non-display area NDA may include a scan driver 211 and an emission control driver 213.

The scan driver 211 may be disposed on the outside of one side of the display area DDA or on one side of the non-display area NDA. The scan driver 211 may include a plurality of driving transistors that generate gate signals based on a gate control signal.

The emission control driver 213 may be disposed on the outside of the other side of the display area DDA or on the other side of the non-display area NDA. The emission control driver 213 may include a plurality of emission control transistors that generate light emitting signals based on an emission control signal.

The display layer DPL included in an embodiment may include a display driver 200 and a plurality of pad electrodes PD in a portion overlapping the sub-area SBA. The plurality of pad electrodes PD may be spaced apart from each other in the first direction DR1, and each pad electrode PD may be connected to each different line.

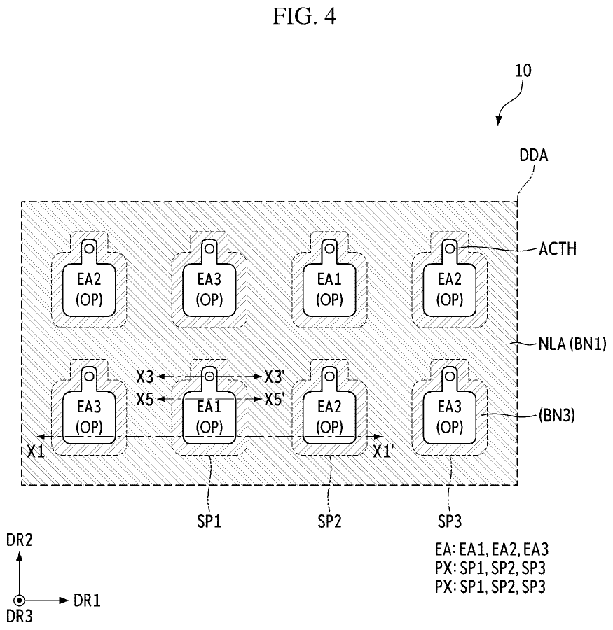

FIG. 4 is a plan view illustrating an arrangement of a plurality of pixels disposed in a display area of FIG. 3.

Referring to FIG. 4, a pixel PX according to an embodiment may include a first sub-pixel SP1, a second sub-pixel SP2, and a third sub-pixel SP3 positioned in a portion overlapping the display area DDA. The first sub-pixel SP1, the second sub-pixel SP2, and the third sub-pixel SP3 may be spaced apart from each other.

The pixel PX may include a light emitting area EA. The light emitting area EA may be a portion from which light is emitted. In an embodiment, for example, the first sub-pixel SP1 may include a first light emitting area EA1, the second sub-pixel SP2 may include a second light emitting area EA2, and the third sub-pixel SP3 may include a third light emitting area EA3.

In an embodiment, the first light emitting area EA1, the second light emitting area EA2, and third light emitting area EA3 may emit light of different colors. In an embodiment, for example, the first light emitting area EA1 may emit red light, the second light emitting area EA2 may emit green light, and the third light emitting area EA3 may emit blue light. However, colors of light emitted by the first light emitting area EA1, the second light emitting area EA2, and the third light emitting area EA3 are not limited thereto, and the first light emitting area EA1, the second light emitting area EA2, and the third light emitting area EA3 may emit a same color as each other in another embodiment.

In an embodiment, the light emitting area EA may be defined by a light emitting opening OP. The light emitting opening OP may be defined by a second element insulating layer (‘DIL2’ in FIG. 5) described later.

In a plan view (or when viewed in the third direction DR3), an anode contact hole ACTH may be positioned in a portion overlapping the light emitting area EA. In a plan view, the anode contact hole ACTH may be positioned inside the light emitting area EA. For convenience of illustration, FIG. 4 shows an embodiment where the anode contact hole ACTH is positioned on one side of an upper portion of the light emitting area EA, but the present disclosure is not limited thereto. A detailed structure of the anode contact hole ACTH will be described later.

The display device 10 according to an embodiment may include a non-light emitting area NLA in a portion overlapping the display area DDA. The non-light emitting area NLA may effectively prevent color mixing of light emitted from the first light emitting area EA1, the second light emitting area EA2, and the third light emitting area EA3.

In a plan view, a bank structure (‘BN’ in FIG. 5) may be positioned in a portion overlapping the non-light emitting area NLA. In a plan view, a third bank layer BN3 included in the bank structure BN may have a shape of a conductive pattern that surrounds the light emitting area EA or the light emitting opening OP. In a plan view, the third bank layers BN3 surrounding the first to third light emitting areas EA1, EA2, and EA3 may be spaced apart from each other.

In addition, a first bank layer BN1 included in the bank structure BN may be entirely formed in a portion overlapping the non-light emitting area NLA. In a plan view, the first bank layer BN1 may electrically connect the third bank layers BN3 surrounding the first to third light emitting areas EA1, EA2, and EA3.

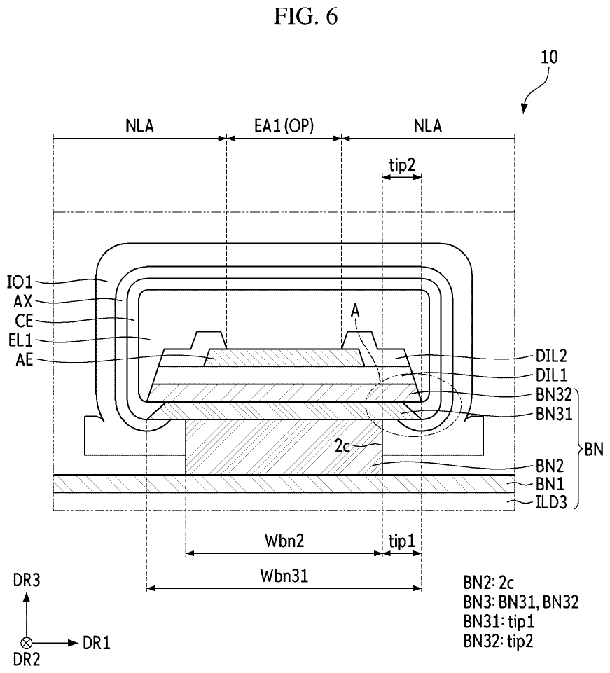

FIG. 5 is a cross-sectional view illustrating an example of the display layer taken along line X1-X1′ of FIG. 4, and FIG. 6 is an enlarged cross-sectional view of a display element layer overlapping a first light emitting area in FIG. 5. FIG. 5 illustrates a cross-sectional structure of the first sub-pixel SP1, the second sub-pixel SP2, and the third sub-pixel SP3 in a portion overlapping the display area DDA of the display device 10.

Referring to FIGS. 5 and 6, in an embodiment of the display device 10, a transistor layer TFTL may be positioned on the substrate SUB. The transistor layer TFTL may include a first buffer layer BF1, a lower metal layer BML, a second buffer layer BF2, a transistor TFT, a gate insulating layer GI, a first insulating layer ILD1, a capacitor electrode CPE, a second insulating layer ILD2, a first connection electrode CNE1, a first via layer VIA1, a second connection electrode CNE2, a second via layer VIA2, and a third insulating layer ILD3.

The first buffer layer BF1 may be positioned on the substrate SUB. The first buffer layer BF1 may include an inorganic film capable of preventing permeation of air or moisture. In an embodiment, for example, the first buffer layer BF1 may include a plurality of inorganic films alternately stacked.

The lower metal layer BML may be positioned on the first buffer layer BF1. The lower metal layer BML may include a conductive metal and may be formed as (or defined by), for example, a single layer or a multi-layer including or made of at least one selected from molybdenum (Mo), aluminum (Al), chromium (Cr), gold (Au), titanium (Ti), nickel (Ni), neodymium (Nd), and copper (Cu), or an alloy thereof.

The second buffer layer BF2 may cover the first buffer layer BF1 and the lower metal layer BML. The second buffer layer BF2 may include an inorganic film capable of preventing permeation of air or moisture. In an embodiment, for example, the second buffer layer BF2 may include a plurality of inorganic films alternately stacked.

The transistor TFT may be disposed on the second buffer layer BF2, and may constitute a pixel circuit. In an embodiment, for example, the transistor TFT may be a driving transistor or a switching transistor of the pixel circuit.

The transistor TFT may include an active layer ACT, a source electrode SE, a drain electrode DE, and a gate electrode GE.

The active layer ACT may be positioned on the second buffer layer BF2. The active layer ACT may overlap the gate electrode GE in the third direction DR3 and may be insulated from the gate electrode GE by the gate insulating layer GI. The drain electrode DE and the source electrode SE may be portions formed by conducting a portion of the active layer ACT.

The gate insulating layer GI may be disposed on the active layer ACT. The gate insulating layer GI may cover the active layer ACT and the second buffer layer BF2, and may insulate the active layer ACT and the gate electrode GE from each other. The gate insulating layer GI may be provided with a contact hole through which the first connection electrode CNE1 penetrates.

The gate electrode GE may be positioned on the gate insulating layer GI. The gate insulating layer GI may be disposed between the gate electrode GE and the active layer ACT.

The gate electrode GE may include a conductive metal and may be formed as, for example, a single layer or a multi-layer including or made of at least one selected from molybdenum (Mo), aluminum (Al), chromium (Cr), gold (Au), titanium (Ti), nickel (Ni), neodymium (Nd), and copper (Cu), or an alloy thereof.

The first insulating layer ILD1 may cover the gate electrode GE and the gate insulating layer GI. The first insulating layer ILD1 may be provided with a contact hole through which the first connection electrode CNE1 penetrates. The contact hole of the first insulating layer ILD1 may be connected to the contact hole of the gate insulating layer GI and a contact hole of the second insulating layer ILD2.

The capacitor electrode CPE may be positioned on the first insulating layer ILD1. The capacitor electrode CPE may overlap the gate electrode GE in the third direction DR3. The capacitor electrode CPE and the gate electrode GE may form a capacitance.

The second insulating layer ILD2 may cover the capacitor electrode CPE and the first insulating layer ILD1. The second insulating layer ILD2 may be provided with a contact hole through which the first connection electrode CNE1 penetrates. The contact hole of the second insulating layer ILD2 may be connected to the contact hole of the first insulating layer ILD1 and the contact hole of the gate insulating layer GI.

The first connection electrode CNE1 may be positioned on the second insulating layer ILD2. The first connection electrode CNE1 may electrically connect the drain electrode DE of the transistor TFT and the second connection electrode CNE2 to each other. The first connection electrode CNE1 may be inserted into the contact holes defined or formed in the first insulating layer ILD1, the second insulating layer ILD2, and the gate insulating layer GI and be in contact with the drain electrode DE of the transistor TFT.

The first via layer VIA1 may be positioned on the first connection electrode CNE1 and the second insulating layer ILD2. The first via layer VIA1 may planarize a lower structure. The first via layer VIA1 may be provided with a contact hole through which the second connection electrode CNE2 penetrates.

The first via layer VIA1 may include an organic insulating material. In an embodiment, for example, the first via layer VIA1 may include at least one selected from an acrylic resin, polyimide, polyamide, benzocyclobutene, a phenol resin, or the like.

The second connection electrode CNE2 may be positioned on the first via layer VIA1. The second connection electrode CNE2 may be positioned in a portion overlapping the light emitting area EA. The second connection electrode CNE2 may be inserted into the contact hole defined or formed in the first via layer VIA1 and be in contact with the first connection electrode CNE1.

The second via layer VIA2 may be positioned on the first via layer VIA1. The second via layer VIA2 may planarize a step formed by the second connection electrode CNE2.

The second via layer VIA2 may include an organic material. In an embodiment, for example, the second via layer VIA2 may include at least one selected from an acrylic resin, a silicone resin, a silicone acrylic resin, an epoxy resin, polyimide, polyamide, benzocyclobutene, a phenol resin, or the like.

The third insulating layer ILD3 may be positioned on the second via layer VIA2. The third insulating layer ILD3 may assist in preventing outgas caused by the organic material of the second via layer VIA2 from permeating into the display element layer EML.

The third insulating layer ILD3 may include an inorganic insulating material. In an embodiment, for example, the third insulating layer ILD3 may include at least one of silicon nitride, silicon oxide, and silicon oxynitride.

The display element layer EML may be disposed on the transistor layer TFTL. The display element layer EML may include a bank structure BN, an element insulating layer DIL, a light emitting element ED, and an element inorganic layer IO.

The bank structure BN may be disposed on the third insulating layer ILD3. The bank structure BN may be positioned in a portion overlapping the light emitting area EA and/or the light emitting opening OP.

The bank structure BN may assist in forming the first to third light emitting elements ED1, ED2, and ED3 in the portions overlapping the first to third light emitting areas EA1, EA2, and EA3, respectively, and may also assist in electrically connecting cathode electrodes CE and cathode auxiliary electrodes AX spaced apart from each other in the first to third light emitting areas EA1, EA2, and EA3.

The bank structure BN may include a first bank layer BN1, a second bank layer BN2, and a third bank layer BN3. The first bank layer BN1, the second bank layer BN2, and the third bank layer BN3 may be sequentially stacked in the third direction DR3.

The first bank layer BN1 may be positioned on the third insulating layer ILD3. The first bank layer BN1 may cover the third insulating layer ILD3 in a portion overlapping the light emitting area EA and the non-light emitting area NLA.

The first bank layer BN1 may be entirely formed in a portion overlapping the light emitting area EA and the non-light emitting area NLA, and may assist in applying a low-potential voltage to the cathode electrode CE.

The first bank layer BN1 may include a conductive metal having etching resistance. In an embodiment, for example, the first bank layer BN1 may include titanium (Ti).

The second bank layer BN2 may be positioned in contact with the first bank layer BN1 in a portion overlapping the light emitting area EA. A plurality of second bank layers BN2 may be formed and may be spaced apart from each other in the first direction DR1. In other words, the plurality of second bank layers BN2 may be positioned in the portions overlapping the first to third light emitting areas EA1, EA2, and EA3, respectively, and each second bank layer BN2 may be formed in an island-shaped conductive pattern.

The second bank layer BN2 positioned in the portion overlapping the first light emitting area EA1, the second bank layer BN2 positioned in the portion overlapping the second light emitting area EA2, and the second bank layer BN2 positioned in the portion overlapping the third light emitting area EA3 may be electrically connected by the first bank layer BN1.

The second bank layer BN2 may include a metal with high electrical conductivity. In an embodiment, for example, the second bank layer BN2 may include aluminum (Al).

The second bank layer BN2 may be formed in a predetermined shape through a wet etching process using a phosphoric acid-based etchant during a process of fabricating the display device 10. The fabricating process will be described later.

The third bank layer BN3 may be positioned in contact with the second bank layer BN2. A plurality of third bank layers BN3 may be formed and may be spaced apart from each other in the first direction DR1. In other words, the plurality of third bank layers BN3 may be positioned in the portions overlapping the first to third light emitting areas EA1, EA2, and EA3, respectively, and each third bank layer BN3 may be formed in an island-shaped conductive pattern.

In an embodiment, the third bank layer BN3 positioned in the portion overlapping the first light emitting area EA1, the third bank layer BN3 positioned in the portion overlapping the second light emitting area EA2, and the third bank layer BN3 positioned in the portion overlapping the third light emitting area EA3 may be electrically connected through the second bank layer BN2 and the first bank layer BN1.

In an embodiment, the third bank layer BN3 may include a first upper conductive layer BN31 and a second upper conductive layer BN32. The first upper conductive layer BN31 may be positioned in contact with the second bank layer BN2, and the second upper conductive layer BN32 may be positioned on the first upper conductive layer BN31.

The first upper conductive layer BN31 may be positioned in contact with the second bank layer BN2 in a portion overlapping the light emitting area EA.

In an embodiment, as illustrated in FIG. 6, a width Wbn31 of the first upper conductive layer BN31 in the first direction DR1 may be greater than a width Wbn2 of the second bank layer BN2. In addition, a thickness of the first upper conductive layer BN31 in the third direction DR3 may be less than a thickness of the second bank layer BN2.

The first upper conductive layer BN31 may have a first tip tip1 that protrudes further in the first direction DR1 than a first side surface 2c of the second bank layer BN2. The first side surface 2c of the second bank layer BN2 and the first tip tip1 of the first upper conductive layer BN31 may form or collectively define an undercut, and thus the bank structure BN may have an overhang structure.

The first upper conductive layer BN31 may include a transparent conductive oxide (TCO) including tin (Sn). In an embodiment, for example, the first upper conductive layer BN31 may include at least one selected from Sn-IGZO, Sn-IZO, Sn-ITGZO, Sn-ZnO, or the like. In an embodiment, the first upper conductive layer BN31 may not include ITO.

The content of tin (Sn) included in the first upper conductive layer BN31 may be in a range from about 18% to about 30%. For example, when the content of tin (Sn) included in the first upper conductive layer BN31 is about 18% or less, the first upper conductive layer BN31 may not include the first tip tip1, because a portion of the first upper conductive layer BN31 is removed by a phosphoric acid-based etchant forming the second bank layer BN2. In other words, when the content of tin (Sn) included in the first upper conductive layer BN31 is about 18% or less, the first upper conductive layer BN31 may have a shape similar to that of the second bank layer BN2. In addition, when the content of tin (Sn) included in the first upper conductive layer BN31 is about 30% or more, it may be difficult to form the first upper conductive layer BN31 itself because it is impossible to form a deposition target.

In the process of fabricating the display device 10, the first upper conductive layer BN31 may be formed in the shape shown in FIG. 6 through a wet etching process. However, the etchant of the wet etching process of forming the first upper conductive layer BN31 and the etchant of the wet etching process of forming the second bank layer BN2 may be different from each other. In an embodiment, for example, the etchant of the wet etching process of forming the first upper conductive layer BN31 may be an etchant having an etching selectivity to aluminum (Al). In other words, the etchant of the wet etching process of forming the first upper conductive layer BN31 may include any etchant that does not etch aluminum (Al).

The second upper conductive layer BN32 may be positioned in contact with the first upper conductive layer BN31 in a portion overlapping the light emitting area EA.

The second upper conductive layer BN32 may have a second tip tip2 that protrudes further in the first direction DR1 than the first side surface 2c of the second bank layer BN2. The second tip tip2 of the second upper conductive layer BN32 may cover the first tip tip1 of the first upper conductive layer BN31 and overlap the first tip tip1 of the first upper conductive layer BN31 in the third direction DR3.

The second upper conductive layer BN32 may include a conductive metal having etching resistance. in an embodiment, for example, the second upper conductive layer BN32 may include titanium (Ti).

In the process of fabricating the display device 10, the second upper conductive layer BN32 may be formed in the shape shown in FIG. 6 through a dry etching process. The fabricating process will be described later.

As the display device 10 according to an embodiment includes the first tip tip1 of the first upper conductive layer BN31 and the second tip tip2 of the second upper conductive layer BN32, the first light emitting element ED1, the second light emitting element ED2, and the third light emitting element ED3 spaced apart from each other may be formed without using a separate fine metal mask in the process of fabricating the display device 10.

In addition, as the display device 10 according to an embodiment includes the first tip tip1 of the first upper conductive layer BN31 and the second tip tip2 of the second upper conductive layer BN32, a contact area between the cathode electrode CE and the cathode auxiliary electrode AX, and the bank structure BN may be increased. A detailed description thereof will be provided later.

The element insulating layer DIL may include a first element insulating layer DIL1 and a second element insulating layer DIL2.

The first element insulating layer DIL1 may be positioned on the third bank layer BN3. The first element insulating layer DIL1 may cover the second upper conductive layer BN32 and may be positioned to overlap the first tip tip1 of the first upper conductive layer BN31 and the second tip tip2 of the second upper conductive layer BN32 in the third direction DR3.

The first element insulating layer DIL1 may separate and insulate the bank structure BN and the anode electrode AE from each other so that the bank structure BN and the anode electrode AE are not in contact with each other.

The first element insulating layer DIL1 may include an inorganic insulating material. in an embodiment, for example, the first element insulating layer DIL1 may include at least one selected from silicon nitride, silicon oxide, and silicon oxynitride.

The second element insulating layer DIL2 may be positioned on the first element insulating layer DIL1. The second element insulating layer DIL2 may define the light emitting opening OP and expose the anode electrode AE in a portion overlapping the light emitting opening OP. In other words, the second element insulating layer DIL2 may be positioned to surround the light emitting opening OP and cover an edge of the anode electrode AE. In the portion overlapping the non-light emitting area NLA, the first element insulating layer DIL1 and the second element insulating layer DIL2 may be in contact with each other.

The second element insulating layer DIL2 may include an inorganic insulating material. In an embodiment, for example, the second element insulating layer DIL2 may include at least one selected from silicon nitride, silicon oxide, and silicon oxynitride.

In an embodiment, for example, where the first element insulating layer DIL1 and the second element insulating layer DIL2 include a same material as each other, the first element insulating layer DIL1 and the second element insulating layer DIL2 may be integrally formed as a single unitary and indivisible part.

The light emitting element ED may be positioned on the bank structure BN. The light emitting element ED may overlap the bank structure BN, the first element insulating layer DIL1, and the second element insulating layer DIL2 in the third direction DR3.

The display device 10 according to an embodiment may be applied to a high-resolution electronic device. Therefore, a plurality of light emitting elements ED included in the display device 10 may be desired to be disposed within a narrow area while securing an appropriate separation distance. Accordingly, in the display device 10 according to an embodiment, the plurality of light emitting elements may be efficiently disposed within the narrow area by forming the light emitting element ED to be positioned on the bank structure BN.

The light emitting element ED may include a first light emitting element ED1 disposed in the first light emitting area EA1, a second light emitting element ED2 disposed in the second light emitting area EA2, and a third light emitting element ED3 disposed in the third light emitting area EA3. The first light emitting element ED1, the second light emitting element ED2, and the third light emitting element ED3 may be spaced apart from each other.

The first light emitting element ED1 may include an anode electrode AE, a first light emitting layer EL1, a cathode electrode CE, and a cathode auxiliary electrode AX, the second light emitting element ED2 may include an anode electrode AE, a second light emitting layer EL2, a cathode electrode CE, and a cathode auxiliary electrode AX, and the third light emitting element ED3 may include an anode electrode AE, a third light emitting layer EL3, a cathode electrode CE, and a cathode auxiliary electrode AX.

The first light emitting element ED1, the second light emitting element ED2, and the third light emitting element ED3 may emit light of different colors. In an embodiment, for example, the first light emitting element ED1 may emit red light, the second light emitting element ED2 may emit green light, and the third light emitting element ED3 may emit blue light. The colors emitted by the first light emitting element ED1, the second light emitting element ED2, and the third light emitting element ED3 may be determined by the first light emitting layer EL1, the second light emitting layer EL2, and the third light emitting layer EL3.

The anode electrode AE may be positioned on the first element insulating layer DIL1. The anode electrode AE may be positioned in a portion overlapping the light emitting area EA and/or the light emitting opening OP.

The anode electrode AE may have a stacked film structure in which a material layer having a high work function, such as indium tin oxide (ITO), indium zinc oxide (IZO), zinc oxide (ZnO), or indium oxide (In₂O₃) and a reflective material layer such as silver (Ag), magnesium (Mg), aluminum (Al), platinum (Pt), lead (Pd), palladium (Pd), gold (Au), nickel (Ni), neodymium (Nd), iridium (Ir), chromium (Cr), lithium (Li), or a mixture thereof are stacked. In an embodiment, for example, the anode electrode AE may have a multilayer structure of ITO/Mg, ITO/MgF, ITO/Ag, and ITO/Ag/ITO, but is not limited thereto.

The first to third light emitting layers EL1, EL2, and EL3 may be positioned on the anode electrode AE. The first to third light emitting layers EL1, EL2, and EL3 may be positioned in portions overlapping the light emitting area EA and the non-light emitting area NLA. The first to third light emitting layers EL1, EL2, and EL3 may overlap the bank structure BN, the first element insulating layer DIL1, and the second element insulating layer DIL2 in the third direction DR3.

The first to third light emitting layers EL1, EL2, and EL3 may be in contact with the anode electrode AE in a portion overlapping the light emitting opening OP and may entirely cover the second element insulating layer DIL2 in the portion overlapping the non-light emitting area NLA.

In some embodiments, the first to third light emitting layers EL1, EL2, and EL3 may cover a portion of the third bank layer BN3 and be in contact with a portion of the first element insulating layer DIL1 in a plan view.

The first light emitting layer EL1 may be positioned in a portion overlapping the first light emitting area EA1, the second light emitting layer EL2 may be positioned in a portion overlapping the second light emitting area EA2, and the third light emitting layer EL3 may be positioned in a portion overlapping the third light emitting area EA3. The first light emitting layer EL1, the second light emitting layer EL2, and the third light emitting layer EL3 may be spaced apart from each other in the portion overlapping the non-light emitting area NLA.

As the display device 10 according to an embodiment includes the first tip tip1 of the first upper conductive layer BN31 and the second tip tip2 of the second upper conductive layer BN32, the first light emitting layer EL1, the second light emitting layer EL2, and the third light emitting layer EL3 spaced apart from each other may be formed without using a separate fine metal mask in the process of fabricating the display device 10. The fabricating process will be described later.

The first to third light layers EL1, EL2, and EL3 may be organic light emitting layers including or made of organic materials. The first to third light emitting layers EL1, EL2, and EL3 may include any commonly used materials.

The first light emitting layer EL1, the second light emitting layer EL2, and the third light emitting layer EL3 may emit light of different colors. In an embodiment, for example, the first light emitting layer EL1 may emit red light, the second light emitting layer EL2 may emit green light, and the third light emitting layer EL3 may emit blue light, but the present disclosure is not limited thereto.

The cathode electrode CE may be positioned on the first to third light emitting layers EL1, EL2, and EL3. The cathode electrode CE may be positioned in the portions overlapping the light emitting area EA and the non-light emitting area NLA. The cathode electrode CE may entirely cover the first to third light emitting layers EL1, EL2, and EL3.

The cathode electrode CE may be in contact with the bank structure BN, and thus may be electrically connected to the bank structure BN. In an embodiment, for example, the cathode electrode CE may be in contact with the first tip tip1 of the first upper conductive layer BN31 and the second tip tip2 of the second upper conductive layer BN32.

The cathode electrode CE includes a metal with high electrical conductivity and a transparent conductive oxide, so that the light generated in the first to third light emitting layers EL1, EL2, and EL3 may be emitted. In an embodiment, for example, the cathode electrode CE may include a material layer having a low work function, such as Li, Ca, LiF/Ca, LiF/Al, Al, Mg, Ag, Pt, Pd, Ni, Au, Nd, Ir, Cr, BaF, Ba, or a compound or mixture thereof (e.g., a mixture of Ag and Mg, etc.).

In an embodiment, the cathode electrode CE positioned in a portion overlapping the first light emitting area EA1, the cathode electrode CE positioned in a portion overlapping the second light emitting area EA2, and the cathode electrode CE positioned in a portion overlapping the third light emitting area EA3 may be spaced apart from each other. The cathode electrodes CE positioned to be spaced apart from each other in the first to third light emitting areas EA1, EA2, and EA3 may be electrically connected through the bank structure BN. In an embodiment, the cathode electrodes CE positioned to be spaced apart from each other in the first to third light emitting areas EA1, EA2, and EA3 may be in contact with third bank layers BN3 positioned to be spaced apart from each other in the first to third light emitting areas EA1, EA2, and EA3, and may be electrically connected to each other through the second bank layer BN2 and the first bank layer BN1 that are electrically connected to the third bank layer BN3.

As the display device 10 according to an embodiment includes the first tip tip1 of the first upper conductive layer BN31 and the second tip tip2 of the second upper conductive layer BN32, the cathode electrodes CE positioned to be spaced apart from each other in the first to third light emitting areas EA1, EA2, and EA3 may be formed without using a separate fine metal mask. The fabricating process will be described later.

The cathode auxiliary electrode AX may be positioned on the cathode electrode CE. The cathode auxiliary electrode AX may be positioned in the portions overlapping the light emitting area EA and the non-light emitting area NLA. The cathode auxiliary electrode AX may entirely cover the cathode electrode CE. The cathode auxiliary electrode AX may assist in electrically connecting the cathode electrode CE.

In an embodiment, the cathode auxiliary electrode AX may be formed integrally with the cathode electrode CE as a single unitary indivisible part, in which case the cathode auxiliary electrode AX may be referred to as the cathode electrode CE.

The cathode auxiliary electrode AX may include a transparent conductive oxide (TCO). In an embodiment, for example, the cathode auxiliary electrode AX may include at least one selected from indium-zinc-oxide (IZO) and indium-tin-oxide (ITO).

In an embodiment, the cathode auxiliary electrode AX positioned in a portion overlapping the first light emitting area EA1, the cathode auxiliary electrode AX positioned in a portion overlapping the second light emitting area EA2, and the cathode auxiliary electrode AX positioned in a portion overlapping the third light emitting area EA3 may be spaced apart from each other. The cathode auxiliary electrodes AX positioned to be spaced apart from each other in the first to third light emitting areas EA1, EA2, and EA3 may be electrically connected through the bank structure BN. In an embodiment, the cathode auxiliary electrodes AX positioned to be spaced apart from each other in the first to third light emitting areas EA1, EA2, and EA3 may be in contact with third bank layers BN3 positioned to be spaced apart from each other in the first to third light emitting areas EA1, EA2, and EA3, and may be electrically connected to each other through the second bank layer BN2 and the first bank layer BN1 that are electrically connected to the third bank layer BN3.

In general, the display device 10 may have a reduced electrical resistance as the contact area between the cathode electrode CE and/or the cathode auxiliary electrode AX and the bank structure BN increases. For example, when the contact area between the cathode electrode CE and/or the cathode auxiliary electrode AX and the bank structure BN is lowered below a certain range, the display device 10 may cause poor reliability such as poor power supply or poor luminance reduction.

Accordingly, as the display device 10 according to an embodiment is formed in a way such that the first upper conductive layer BN31 and the second upper conductive layer BN32 include the first tip tip1 and the second tip tip2, and the step is formed between the first tip tip1 and the second tip tip2, the contact area between the cathode electrode CE and/or the cathode auxiliary electrode AX, and the bank structure BN may be increased. The detailed structures of the first tip tip1 and the second tip tip2 are described later.

The element inorganic layer IO may be positioned on the light emitting element ED. The element inorganic layer IO may completely cover the light emitting element ED and prevent oxygen or moisture from permeating into the light emitting element ED.

The element inorganic layer IO may include an inorganic insulating material. In an embodiment, for example, the element inorganic layer IO may include at least one selected from silicon nitride, silicon oxide, and silicon oxynitride.

The element inorganic layer IO may include a first element inorganic layer IO1, a second element inorganic layer IO2, and a third element inorganic layer IO3. The first element inorganic layer IO1 may be disposed on the first light emitting element ED1 in the first light emitting area EA1, the second element inorganic layer IO2 may be disposed on the second light emitting element ED2 in the second light emitting area EA2, and the third element inorganic layer IO3 may be disposed on the third light emitting element ED3 in the third light emitting area EA3. The first element inorganic layer IO1, the second element inorganic layer IO2, and the third element inorganic layer IO3 may be spaced apart from each other in a portion overlapping the non-light emitting area NLA.

In an embodiment, as shown in FIG. 5, the first element inorganic layer IO1, the second element inorganic layer IO2, and the third element inorganic layer IO3 may be formed in (or directly on) a same layer as each other, but in the process of fabricating the display device 10, the first element inorganic layer IO1 may be formed after the first light emitting element ED1 is formed, the second element inorganic layer IO2 may be formed after the second light emitting element ED2 is formed, and the third element inorganic layer IO3 may be formed after the third light emitting element ED3 is formed. The fabricating process will be described later.

The thin film encapsulation layer TFEL may be positioned on the display element layer EML. The thin film encapsulation layer TFEL may include an organic encapsulation layer TFE1 and an inorganic encapsulation layer TFE3.

The organic encapsulation layer TFE1 according to an embodiment may be positioned on the element inorganic layer IO. In an embodiment, for example, the organic encapsulation layer TFE1 may be entirely in contact with and cover the first element inorganic layer IO1, the second element inorganic layer IO2, and the third element inorganic layer IO3.

The organic encapsulation layer TFE1 may planarize the step (or a stepped structure) formed according to a profile of the lower structure. The organic encapsulation layer TFE1 may fill a spaced portion between the cathode auxiliary electrode AX and the first bank layer BN1 in the portion overlapping the non-light emitting area NLA.

The organic encapsulation layer TFE1 may include a polymer-based material. In an embodiment, for example, the organic encapsulation layer TFE1 may include at least one selected from an acrylic resin, a silicone resin, an epoxy resin, a silicone acrylic resin, polyimide, and polyethylene.

The inorganic encapsulation layer TFE3 may be positioned on the organic encapsulation layer TFE1. The inorganic encapsulation layer TFE3 may protect the lower structure from permeation of moisture and oxygen. In another embodiment, the inorganic encapsulation layer TFE3 may also be omitted.

The inorganic encapsulation layer TFE3 may include an inorganic insulating material. In an embodiment, for example, the inorganic encapsulation layer TFE3 may include at least one selected from silicon nitride, silicon oxide, and silicon oxynitride.

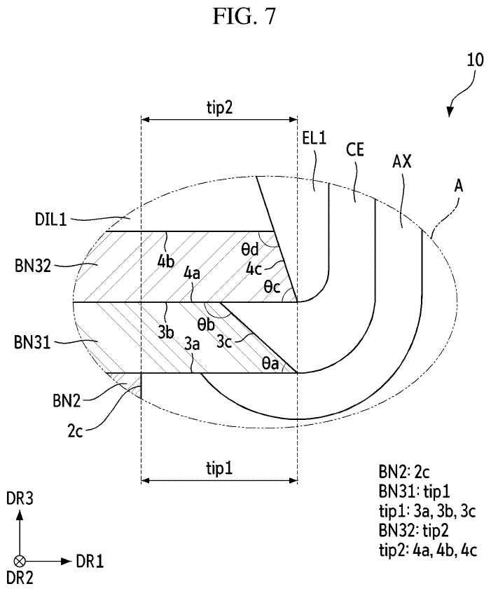

FIG. 7 is an enlarged cross-sectional view of area ‘A’ in FIG. 6.

Referring to FIG. 7 in addition to FIGS. 1 to 6, the first upper conductive layer BN31 according to an embodiment may include a first tip tip1 that protrudes further in the first direction DR1 than the first side surface 2c of the second bank layer BN2, and the first tip tip1 may have a regular tapered or trapezoidal shape in a cross-section.

As the first upper conductive layer BN31 according to an embodiment includes tin (Sn) in a range from about 18% to about 30%, the first upper conductive layer BN31 may have a low etching rate when the first upper conductive layer BN31 is formed by performing a wet etching process in the fabricating process. Accordingly, the first upper conductive layer BN31 may be formed in the shape shown in FIG. 7. The fabricating process will be described later.

The first tip tip1 may include a first surface 3a, a second surface 3b, and a first inclined surface 3c. The first surface 3a of the first tip tip1 may be one surface facing the second bank layer BN2, the second surface 3b may be one surface opposite to the first surface 3a, and the first inclined surface 3c may be one surface connecting the first surface 3a and the second surface 3b. The first inclined surface 3c may have a shape inclined between the first direction DR1 and the third direction DR3.

In an embodiment, a first inclined angle θa formed by the first surface 3a and the first inclined surface 3c included in the first tip tip1 may be an acute angle, and a second inclined angle θb formed by the second surface 3b and the first inclined surface 3c included in the first tip tip1 may be an obtuse angle. The first inclined angle θa and the second inclined angle θb included in the first tip tip1 may be formed in the shape shown in FIG. 7, as the first upper conductive layer BN31 is formed by the wet etching process in the fabricating process.

In an embodiment, the second tip tip2 of the second upper conductive layer BN32 may cover the first tip tip1 of the first upper conductive layer BN31. As described above, the first tip tip1 and the second tip tip2 may overlap each other in the third direction DR3.

An undercut may be formed between the second tip tip2 of the second upper conductive layer BN32 and the first tip tip1 of the first upper conductive layer BN31. The display device 10 according to an embodiment may increase the contact area between the cathode electrode CE and/or the cathode auxiliary electrode AX and the third bank layer BN3 by forming the undercut between the first tip tip1 and the second tip tip2 to include a step portion.

In an embodiment, the cathode electrode CE and/or the cathode auxiliary electrode AX may be in contact with the first inclined surface 3c of the first tip tip1, and the cathode auxiliary electrode AX may be in contact with the first surface 3a. In an embodiment, as shown in FIG. 7, the cathode electrode CE may entirely fill the undercut, but the present disclosure is not limited thereto.

As the second upper conductive layer BN32 according to an embodiment includes titanium (Ti), the second upper conductive layer BN32 may be formed by performing a dry etching process during the fabricating process. Accordingly, the second upper conductive layer BN32 may have a second tip tip2 that protrudes further in the first direction DR1 than the first side surface 2c of the second bank layer BN2, and the second tip tip2 may have a regular tapered or trapezoidal shape in a cross-section.

In an embodiment, the second tip tip2 included in the second upper conductive layer BN32 may include a third surface 4a, a fourth surface 4b, and a second inclined surface 4c. The third surface 4a of the second tip tip2 may be one surface facing the first upper conductive layer BN31, the fourth surface 4b may be one surface opposite to the third surface 4a, and the second inclined surface 4c may be one surface connecting the third surface 4a and the fourth surface 4b. The second inclined surface 4c may have a shape inclined between the first direction DR1 and the third direction DR3.

In an embodiment, a first inclined angle θc formed by the third surface 4a and the second inclined surface 4c included in the second tip tip2 may be an acute angle, and a second inclined angle θd formed by the fourth surface 4b and the second inclined surface 4c included in the second tip tip2 may be an obtuse angle.

In an embodiment, the first tip tip1 and the second tip tip2 may have different structures as being performed in different processes. In an embodiment, the first inclined angle θc included in the second tip tip2 may be greater than the first inclined angle θa included in the first tip tip1. In the display device 10 according to an embodiment, the first upper conductive layer BN31 and the second upper conductive layer BN32 include different materials from each other and are formed through different processes from each other, such that the first inclined angle θc included in the second tip tip2 is greater than the first inclined angle θa included in the first tip tip1.

In an embodiment, the cathode electrode CE may be in contact with the second inclined surface 4c and/or the third surface 4a of the second tip tip2.

In an embodiment, the first element insulating layer DIL1 may entirely cover the fourth surface 4b of the second upper conductive layer BN32.

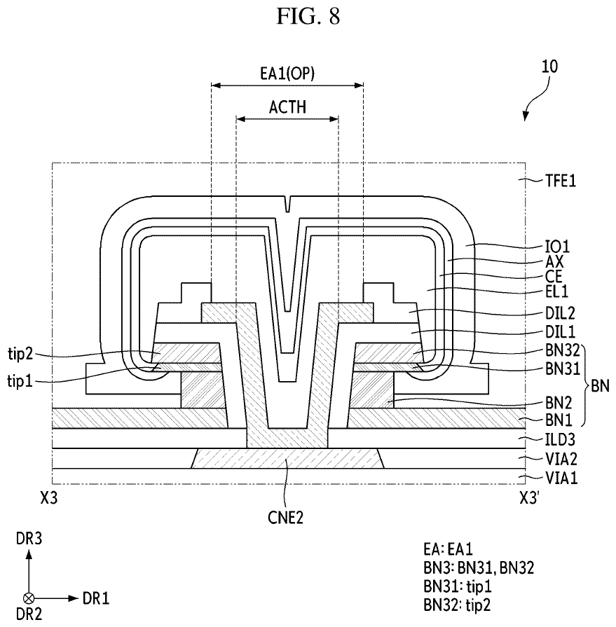

FIG. 8 is a cross-sectional view illustrating an example of the display layer taken along line X3-X3′ of FIG. 4. FIG. 8 illustrates a cross-sectional structure of the display element layer EML overlapping the anode contact hole ACTH. Hereinafter, any repetitive detailed description of the same or like elements as those described above will be omitted, and the characteristics of the display element layer EML overlapping the anode contact hole ACTH will be mainly described.

Referring to FIG. 8 in addition to FIGS. 1 to 7, in an embodiment, the anode contact hole ACTH may overlap the light emitting area EA.

In an embodiment, the anode contact hole ACTH may be positioned in a portion overlapping the light emitting opening OP defined by the second element insulating layer DIL2. The anode contact hole ACTH may be formed to penetrate through the bank structure BN and the third insulating layer ILD3, and the second connection electrode CNE2 may be exposed in a portion overlapping the anode contact hole ACTH.

In an embodiment, the first bank layer BN1, the second bank layer BN2, and the first upper conductive layer BN31 and the second upper conductive layer BN32 of the third bank layer BN3 may be positioned to surround the anode contact hole ACTH. In such an embodiment, the first tip tip1 included in the first upper conductive layer BN31 and the second tip tip2 included in the second upper conductive layer BN32 may be positioned to surround the anode contact hole ACTH.

In an embodiment, the first element insulating layer DIL1 may be disposed between the anode electrode AE and the first bank layer BN1, the second bank layer BN2, and the first upper conductive layer BN31 and the second upper conductive layer BN32 of the third bank layer BN3. In an embodiment, the anode electrode AE may cover along the step formed by the first element insulating layer DIL1. Accordingly, the anode electrode AE may include a step (or have a stepped structure) in a portion overlapping the anode contact hole ACTH.

In the portion overlapping the anode contact hole ACTH, the anode electrode AE and the second connection electrode CNE2 can be in contact and electrically connected. Referring to FIG. 5, the anode electrode AE may be electrically connected to the transistor TFT through the second connection electrode CNE2.

In an embodiment, the first light emitting layer EL1 may cover along the step formed by the anode electrode AE in a portion overlapping the anode contact hole ACTH. Accordingly, in an embodiment, the first light emitting layer EL1 may include a step in the portion overlapping the anode contact hole ACTH.

In an embodiment, the cathode electrode CE may cover along the step formed by the anode electrode AE in a portion overlapping the anode contact hole ACTH. Accordingly, in an embodiment, the cathode electrode CE may include a step in the portion overlapping the anode contact hole ACTH.

In an embodiment, the cathode auxiliary electrode AX may cover along the step formed by the anode electrode AE in a portion overlapping the anode contact hole ACTH. Accordingly, in an embodiment, the cathode auxiliary electrode AX may include a step in the portion overlapping the anode contact hole ACTH.

In an embodiment, the first element inorganic layer IO1 may cover along the step formed by the anode electrode AE in a portion overlapping the anode contact hole ACTH. Accordingly, in an embodiment, the first element inorganic layer IO1 may include a step in the portion overlapping the anode contact hole ACTH. However, the present specification is not limited thereto, and the first element inorganic layer IO1 may not include the step in the portion overlapping the anode contact hole ACTH. Any repetitive detailed descriptions thereof will be omitted.

For convenience of illustration and description, the structure and characteristics of the anode contact hole ACTH overlapping the first light emitting area EA1 are illustrated and then described, but the structure and characteristics of the anode contact hole ACTH overlapping the second light emitting area EA2 and the third light emitting area EA3 may be the same as the structure and characteristics of the anode contact hole ACTH overlapping the first light emitting area EA1.

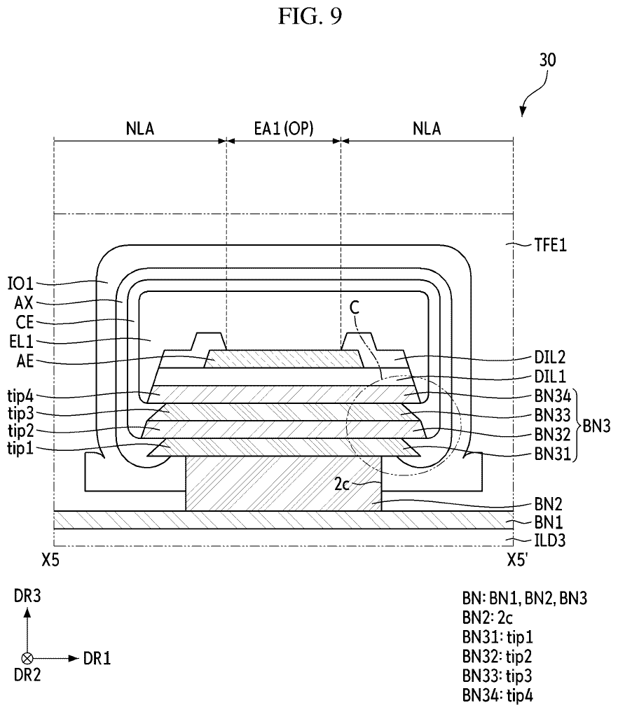

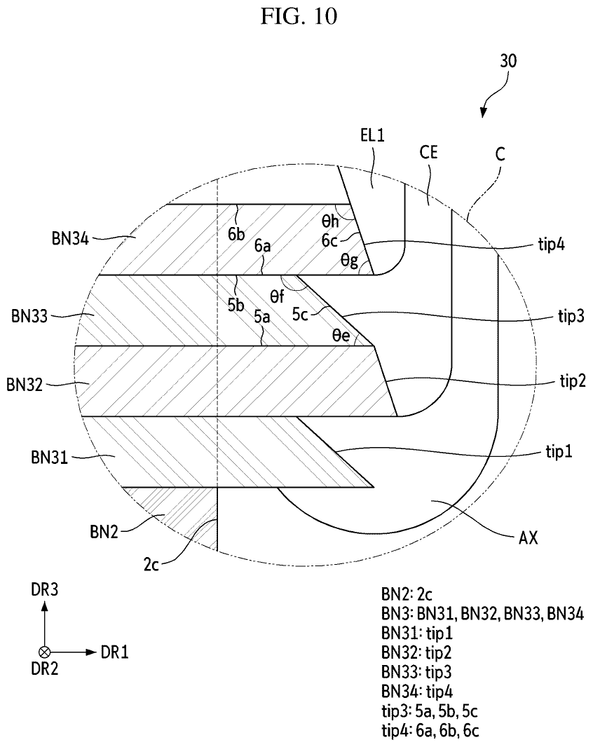

FIG. 9 is a cross-sectional view illustrating an example of the display layer taken along line X5-X5′ of FIG. 4 according to another embodiment, and FIG. 10 is an enlarged cross-sectional view of area ‘C’ of FIG. 9.

Referring to FIGS. 9 and 10 in addition to FIGS. 1 to 8, a bank structure BN included in a display device 30 according to an embodiment may include a first bank layer BN1, a second bank layer BN2, and a third bank layer BN3, and the third bank layer BN3 may include a first upper conductive layer BN31, a second upper conductive layer BN32, a third upper conductive layer BN33, and a fourth upper conductive layer BN34.

The first upper conductive layer BN31 and the second upper conductive layer BN32 included in the display device 30 may have the same structure and characteristics as the first upper conductive layer BN31 and the second upper conductive layer BN32 included in the display device 10. Hereinafter, any repetitive detailed description of the same or like elements of the display device 30 of FIGS. 9 and 10 as those described above will be omitted and differences will be mainly described.

The third upper conductive layer BN33 included in the display device 30 may be positioned in contact with the second upper conductive layer BN32 in a portion overlapping the light emitting area EA.

The third upper conductive layer BN33 may have a third tip tip3 that protrudes further in the first direction DR1 than a first side surface 2c of the second bank layer BN2. The third tip tip3 of the third upper conductive layer BN33 may overlap the first tip tip1 and the second tip tip2 in the third direction DR3.

The third upper conductive layer BN33 may include the same material as the first upper conductive layer BN31. In an embodiment, for example, the third upper conductive layer BN33 may include a transparent conductive oxide (TCO) including tin (Sn), and the content of tin (Sn) may be in a range from about 18% to about 30%. In an embodiment, for example, the third upper conductive layer BN33 may include Sn—IGZO, Sn—IZO, Sn—ITGZO, Sn—ZnO, etc. In an embodiment, the third upper conductive layer BN33 may not include ITO.

In a process of fabricating the display device 30, the third upper conductive layer BN33 may be formed in the shape currently illustrated through a wet etching process. An etchant of the wet etching process forming the third upper conductive layer BN33 may be the same as the etchant of the wet etching process forming the first upper conductive layer BN31.

In an embodiment, the third tip tip3 included in the third upper conductive layer BN33 may include a first surface 5a, a second surface 5b, and a first inclined surface 5c. The first surface 5a of the third tip tip3 may be one surface facing the second upper conductive layer BN32, the second surface 5b may be one surface opposite to the first surface 5a, and the first inclined surface 5c may be one surface connecting the first surface 5a and the second surface 5b. The first inclined surface 5c may have a shape inclined between the first direction DR1 and the third direction DR3.

The third tip tip3 may have a regular tapered shape or a trapezoidal shape. Specifically, a first inclined angle θe formed by the first surface 5a and the first inclined surface 5c included in the third tip tip3 may be an acute angle, and a second inclined angle θf formed by the second surface 5b and the first inclined surface 5c included in the third tip tip3 may be an obtuse angle.

In an embodiment, an undercut may be formed between a fourth tip tip4 of the fourth upper conductive layer BN34 and the third tip tip3 of the third upper conductive layer BN33. The display device 30 according to an embodiment may increase a contact area between the cathode electrode CE and/or the cathode auxiliary electrode AX and the third bank layer BN3 by forming the undercut between the third tip tip3 and the fourth tip tip4 to include a step portion.

In an embodiment, the cathode electrode CE and/or the cathode auxiliary electrode AX may be in contact with the first inclined surface 5c of the third tip tip3. In an embodiment, as shown in FIG. 9, the cathode electrode CE may entirely fill the undercut, but the present disclosure is not limited thereto.

The fourth upper conductive layer BN34 may be positioned in contact with the third upper conductive layer BN33 in a portion overlapping the light emitting area EA.

The fourth upper conductive layer BN34 may have a fourth tip tip4 that protrudes further in the first direction DR1 than the first side surface 2c of the second bank layer BN2. The fourth tip tip4 of the fourth upper conductive layer BN34 may overlap the first tip tip1, the second tip tip2, and the third tip tip3 in the third direction DR3.

The fourth upper conductive layer BN34 may include the same material as the second upper conductive layer BN32. In an embodiment, for example, the fourth upper conductive layer BN34 may include a conductive metal having etching resistance and may include titanium (Ti).

In the process of fabricating the display device 30, the fourth upper conductive layer BN34 may be formed in the shape shown in FIG. 9 through a dry etching process. The fourth tip tip4 may have a regular tapered shape or a trapezoidal shape.

In an embodiment, the fourth tip tip4 included in the fourth upper conductive layer BN34 may include a third surface 6a, a fourth surface 6b, and a second inclined surface 6c. The third surface 6a of the fourth tip tip4 may be one surface facing the third upper conductive layer BN33, the fourth surface 6b may be one surface opposite to the third surface 6a, and the second inclined surface 6c may be one surface connecting the third surface 6a and the fourth surface 6b. The second inclined surface 6c may have a shape inclined between the first direction DR1 and the third direction DR3.

In an embodiment, a first inclined angle θg formed by the third surface 6a and the second inclined surface 6c included in the fourth tip tip4 may be an acute angle, and a second inclined angle θh formed by the fourth surface 6b and the second inclined surface 6c included in the fourth tip tip4 may be an obtuse angle.

In an embodiment, the third tip tip3 and the fourth tip tip4 may have different structures as being performed in different processes. In an embodiment, for example, the first inclined angle θg included in the fourth tip tip4 may be greater than the first inclined angle θe included in the third tip tip3. In the display device 30 according to an embodiment, the third upper conductive layer BN33 and the fourth upper conductive layer BN34 may include different materials and be formed through different processes, such that the first inclined angle θg included in the fourth tip tip4 has a larger value than the first inclined angle θe included in the third tip tip3.

The first element insulating layer DIL1 may entirely cover the fourth surface 6b of the fourth upper conductive layer BN34.

As the third bank layer BN3 includes the first tip tip1, the second tip tip2, the third tip tip3, and the fourth tip tip4, the display device 30 may include a first light emitting element ED1, a second light emitting element ED2, and a third light emitting element ED3 spaced apart from each other without a separate fine metal mask in the fabricating process.

In addition, as the third bank layer BN3 includes the first tip tip1, the second tip tip2, the third tip tip3, and the fourth tip tip4, the display device 30 may increase the contact area between the cathode electrode CE and the cathode auxiliary electrode AX, and the bank structure BN. Accordingly, electrical resistance of the display device 30 may be reduced.

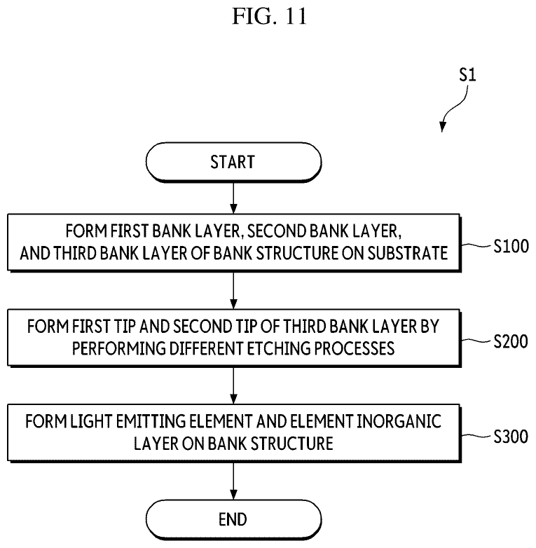

FIG. 11 is a flowchart illustrating an embodiment of a method for fabricating the display element layer of FIG. 5.

Referring to FIG. 11 in addition to FIGS. 1 to 10, a method (S1) for fabricating a display element layer EML included in a display device 10 according to an embodiment may a process (S100) of forming a first bank layer, a second bank layer, and a third bank layer of a bank structure on a substrate, a process (S200) of forming a first tip and a second tip of the third bank layer by performing different etching processes, and a process (S300) of forming a light emitting element and an element inorganic layer on the bank structure.

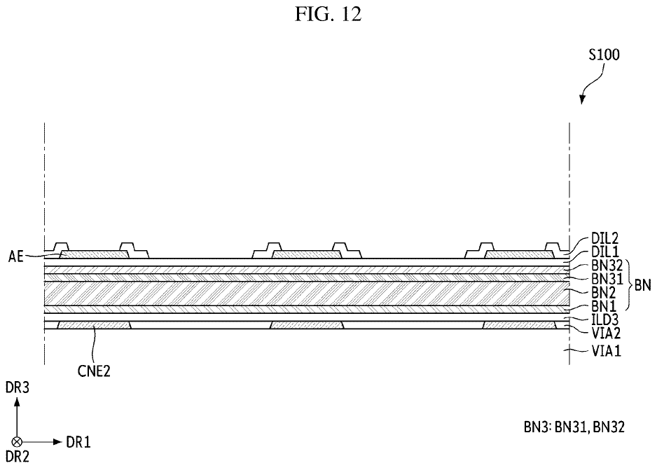

FIG. 12 is a cross-sectional view for describing process S100 of FIG. 11.

A process (S100) of forming a first bank layer, a second bank layer, and a third bank layer of a bank structure on a substrate will be described with reference to FIG. 12.

First, a plurality of second connection electrodes CNE2 are formed on a first via layer VIA1, and a second via layer VIA2, a third insulating layer ILD3, a bank structure BN, and a first element insulating layer DIL1 are entirely formed.

In such a process, the bank structure BN may include a first bank layer BN1, a second bank layer BN2, and a third bank layer BN3 that are sequentially stacked, and the third bank layer BN3 may include a first upper conductive layer BN31 and a second upper conductive layer BN32.

In such a process, the second bank layer BN2 and the first upper conductive layer BN31 and the second upper conductive layer BN32 of the third bank layer BN3 may include different materials. In an embodiment, for example, the first upper conductive layer BN31 and the second upper conductive layer BN32 may include a material having greater etching resistance than the second bank layer BN2. Any repetitive detailed descriptions thereof will be omitted.

Although not illustrated in the drawings, a thin film transistor layer TFTL including the first via layer VIA1 and the second via layer VIA2 may be positioned on the substrate SUB, and a detailed structure of the thin film transistor layer TFTL is the same as that illustrated in FIG. 5.

Next, an anode electrode AE and a second element insulating layer DIL2 are formed on the first element insulating layer DIL1. In such a process, the anode electrode AE may be formed through a deposition process and a patterning process including at least one of the above-mentioned conductive metals, and the second element insulating layer DIL2 may be formed through a deposition process and a patterning process including at least one of the above-mentioned inorganic insulating materials.

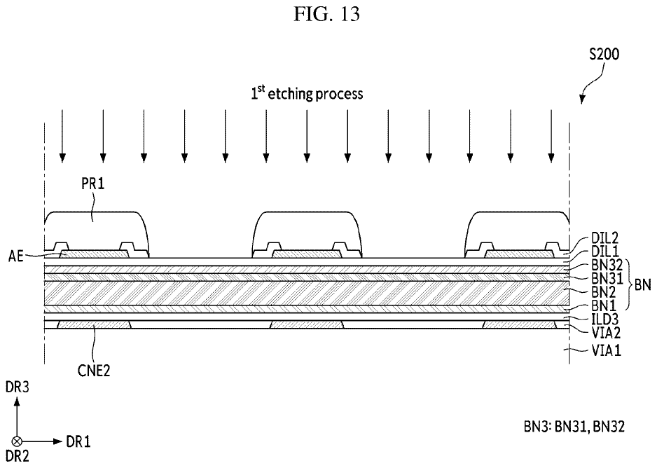

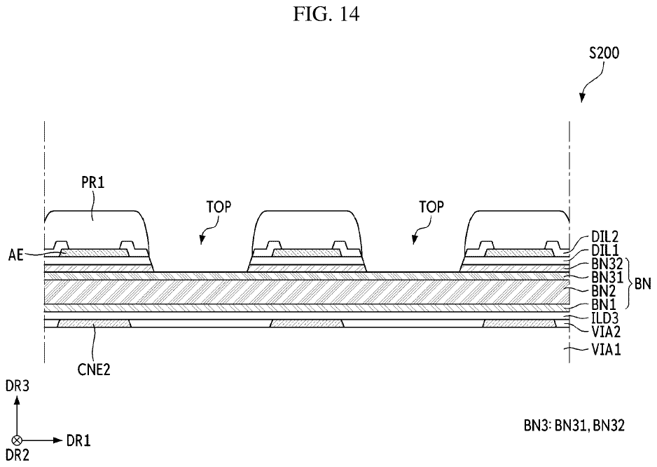

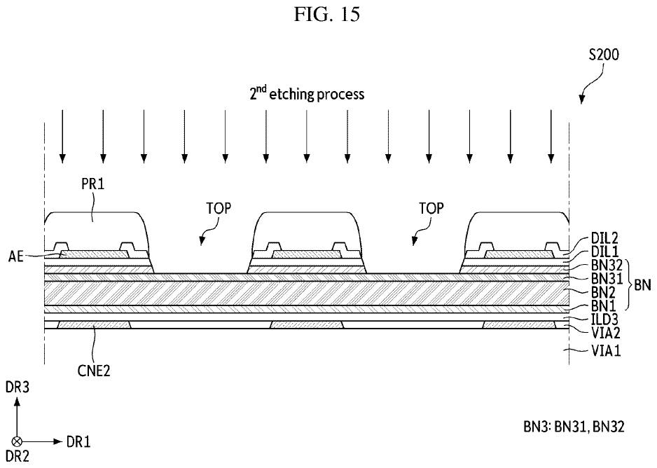

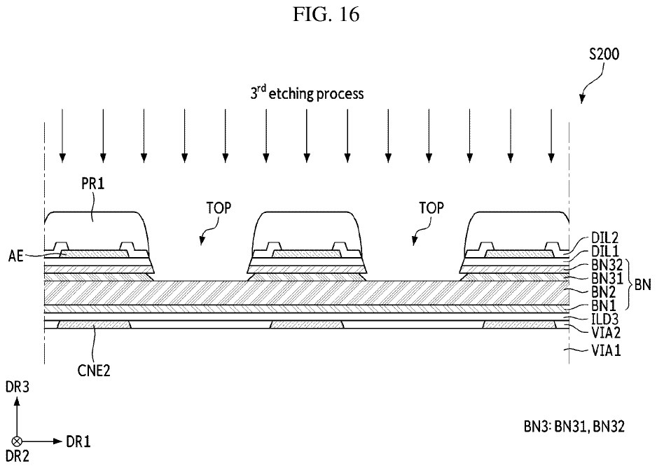

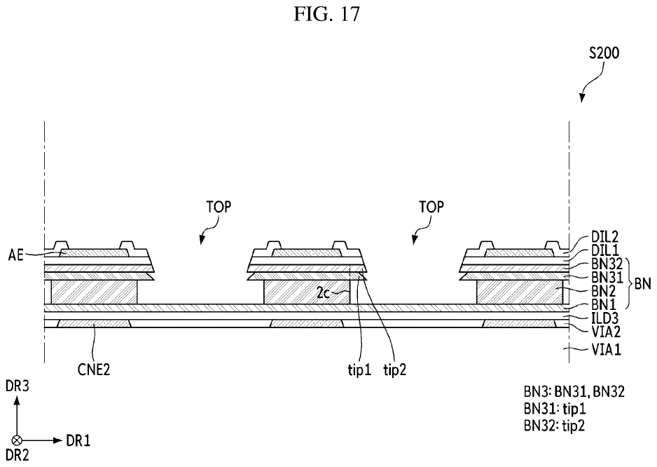

FIGS. 13 to 17 are cross-sectional views for describing process S200 of FIG. 11.

A process (S200) of forming a first tip and a second tip of the third bank layer by performing different etching processes will be described with reference to FIGS. 13 to 17.

First, a photoresist PR1 is formed on the anode electrode AE and the second element insulating layer DIL2, and a first etching process is performed. In such a process, a plurality of photoresists PR1 may be formed, and the photoresists PR1 may entirely cover the anode electrode AE and the second element insulating layer DIL2.

In such a process, the first etching process may be performed as a dry etching process. In an embodiment, for example, the dry etching process may be performed through a reactive ion etching (RIE) process using reactive gases such as CHF₃, CH₃F, CH₂F₂, CHF₆, CF₄, C₂F₆, and C₃F₆, and sputtering gases such as Ar, and O₂/Ar. In such an embodiment, an inductively coupled plasma (ICP) source or a capacitively coupled plasma (CCP) source may be used as a plasma source.

Through such a process, the first element insulating layer DIL1 and the second upper conductive layer BN32 that do not overlap the photoresist PR1 may be removed at once. Accordingly, a temporary opening TOP may be formed in a portion that does not overlap the photoresist PR1, and the first upper conductive layer BN31 may be exposed in a portion overlapping the temporary opening TOP.

Next, a second etching process is performed using the photoresist PR1 as it is. The second etching process may be performed as a wet etching process. In such a process, an etchant may include any etchant that is specifically designed to etch a transparent conductive oxide (TCO) and has an etching selectivity to aluminum (Al). In an embodiment, for example, the etchant used in this process may include oxalic acid, inorganic acid, etc.

In such a process, the first upper conductive layer BN31 that does not overlap the photoresist PR1 may be removed, and the second bank layer BN2 may be exposed in the portion overlapping the temporary opening TOP. Through the present process, the first upper conductive layer BN31 may have a regular tapered or trapezoidal shape. Any repetitive detailed descriptions thereof will be omitted.

Next, a third etching process is performed using the photoresist PR1 as it is. The third etching process may be performed as a wet etching process. The etchant used in the present process may include phosphoric acid. In an embodiment, for example, the composition of the etchant may include about 40% or more and about 60% or less of phosphoric acid, about 2% or more and about 9% or less of nitric acid, and about 5% or more and about 15% or less of acetic acid.

In such a process, the second bank layer BN2 that does not overlap the photoresist PR1 can be completely removed, and the first bank layer BN1 may be exposed in the portion overlapping the temporary opening TOP.

In such a process, the second bank layer BN2 may have a higher etching rate than the first upper conductive layer BN31 and the second upper conductive layer BN32. Accordingly, the first side surface 2c of the second bank layer BN2 may be formed to be more depressed in the first direction DR1 than the first upper conductive layer BN31 and the second upper conductive layer BN32.

In such a process, tin (Sn) included in the first upper conductive layer BN31 in the content of about 18% or more and about 30% or less may be adsorbed with phosphate (PO 4-) included in a phosphoric acid etching solution, thereby providing etching resistance. As a result, the first upper conductive layer BN31 does not react to the etching solution of the third etching process and may maintain the shape of the first tip tip1 that protrudes further in the first direction DR1 than the first side surface 2c of the second bank layer BN2.

In addition, the second upper conductive layer BN32 of the third bank layer BN3 and titanium (Ti) included in the first bank layer BN1 may have etching resistance against a wet etchant. Accordingly, the second upper conductive layer BN32 does not react to the etching solution of the third etching process and may maintain the shape of the second tip tip2 that protrudes further in the first direction DR1 than the first side surface 2c of the second bank layer BN2, and the first bank layer BN1 may remain without being removed.

Through this process, an undercut may be formed between the first side surface 2c of the second bank layer BN2 and the third bank layer BN3, and the bank structure BN may have an overhang structure. Although not illustrated in the drawing, the photoresist PR1 may be removed by performing an ashing process.

The display device 10 according to an embodiment may be easily fabricated by performing the first etching process, the second etching process, and the third etching process using the same photoresist PR1.

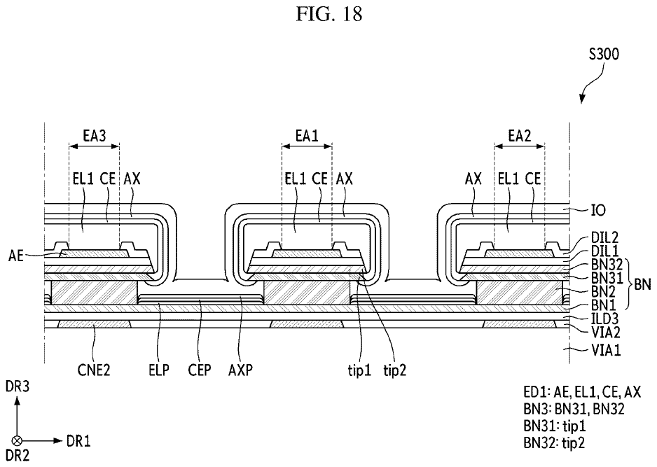

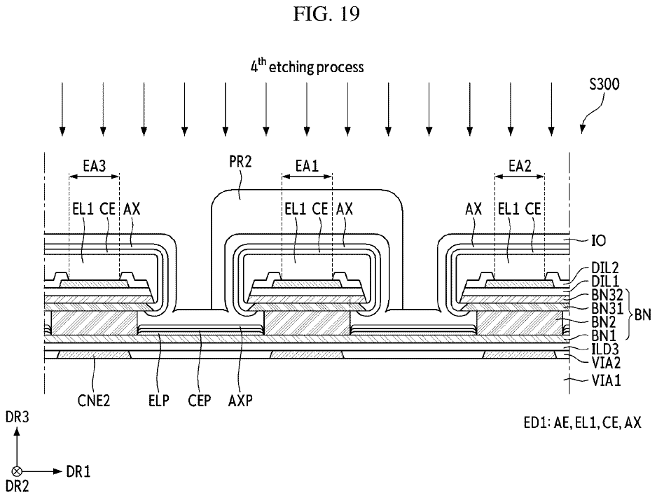

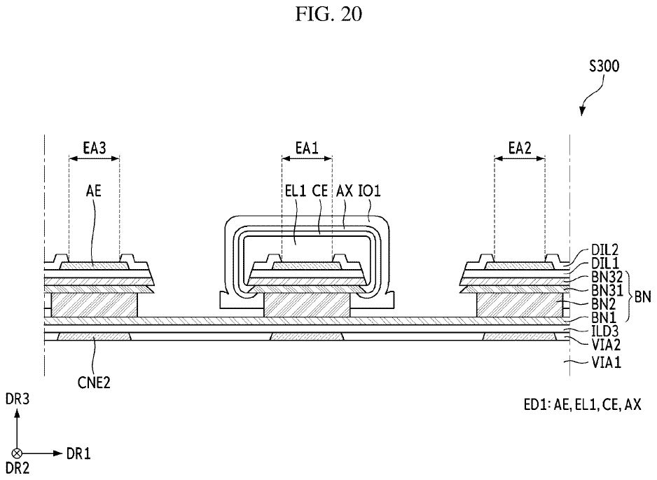

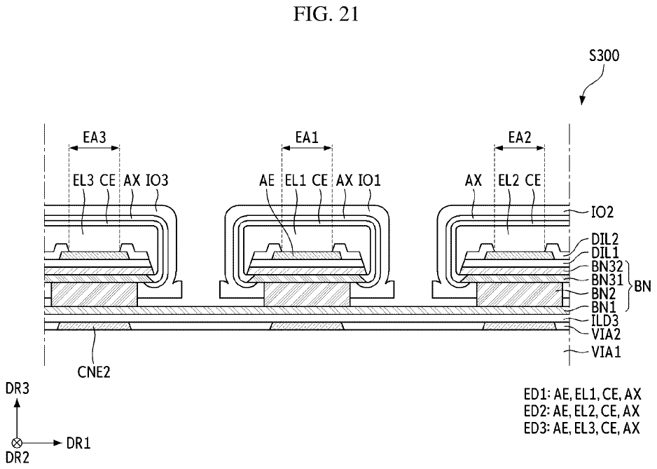

FIGS. 18 to 21 are cross-sectional views for describing process S300 of FIG. 11.

A process (S300) of forming a light emitting element and an element inorganic layer on the bank structure will be described with reference to FIGS. 18 to 21.

First, a first light emitting element ED1 is formed by depositing a first light emitting layer EL1, a cathode electrode CE, and a cathode auxiliary electrode AX on the anode electrode AE.

In such a process, the process of forming the first light emitting layer EL1 may be performed through a thermal deposition process. The process of forming the first light emitting layer EL1 may be performed through entire surface deposition without a separate fine metal mask.

Accordingly, in such a process, the material forming the first light emitting layer EL1 may be formed not only on the anode electrode AE overlapping the first light emitting area EA1, but may also be positioned on the anode electrodes AE positioned in portions overlapping the second light emitting area EA2 and the third light emitting area EA3. The first light emitting layers EL1 positioned in portions overlapping the first to third light emitting areas EA1, EA2, and EA3 may be spaced apart from each other.

In addition, the material forming the first light emitting layer EL1 may also be formed on the first bank layer BN1. The material forming the first light emitting layer EL1 positioned on the anode electrode AE and the material forming the first light emitting layer EL1 positioned on the first bank layer BN1 may be spaced apart from each other. The material forming the first light emitting layer EL1 temporarily positioned on the first bank layer BN1 may be named an organic pattern ELP.

In such a process, the process of forming the cathode electrode CE may be performed through a thermal deposition process or a sputtering process. The process of forming the cathode electrode CE may have a higher step coverage than the process of forming the first light emitting layer EL1. Therefore, the cathode electrode CE may entirely cover the first light emitting layer EL1.

In such a process, the process of forming the cathode electrode CE may be performed through entire surface deposition without a separate fine metal mask. Accordingly, the material forming the cathode electrode CE may be formed not only on the first light emitting layer EL1 overlapping the first light emitting area EA1, but may also be positioned on the first light emitting layer EL1 positioned in portions overlapping the second light emitting area EA2 and the third light emitting area EA3. The cathode electrodes CE positioned in the portions overlapping the first to third light emitting areas EA1, EA2, and EA3 may be spaced apart from each other.

In addition, the material forming the cathode electrode CE may be formed not only on the first light emitting layer EL1, but also on the organic pattern ELP. The material forming the cathode electrode CE positioned on the first light emitting layer EL1 and the material forming the cathode electrode CE positioned on the organic pattern ELP may be spaced apart from each other. The material forming the cathode electrode CE temporarily formed on the first bank layer BN1 may be referred to as an electrode pattern CEP.

In such a process, the cathode electrode CE may be in contact with and cover the first tip tip1 of the first upper conductive layer BN31 and the second tip tip2 of the second upper conductive layer BN32. As the display device 10 according to an embodiment includes the first tip tip1 of the first upper conductive layer BN31 and the second tip tip2 of the second upper conductive layer BN32, a contact area between the cathode electrode CE and the bank structure BN may be increased, thereby reducing electrical resistance of the display device 10. Any repetitive detailed descriptions thereof will be omitted.

The process of forming the cathode auxiliary electrode AX may be performed through a sputtering process. The process of forming the cathode auxiliary electrode AX may have a higher step coverage than the process of forming the cathode electrode CE. Therefore, the cathode auxiliary electrode AX may entirely cover the cathode electrode CE. In an embodiment, for example, the cathode electrode CE and the cathode auxiliary electrode AX may be integrally formed as a single unitary indivisible part.

In such a process, the process of forming the cathode auxiliary electrode AX may be performed through entire surface deposition without a separate fine metal mask. Accordingly, the material forming the cathode auxiliary electrode AX may be formed not only on the cathode electrode CE overlapping the first light emitting area EA1, but may also be positioned on the cathode electrode CE positioned in portions overlapping the second light emitting area EA2 and the third light emitting area EA3. The cathode auxiliary electrodes AX positioned in the portions overlapping the first to third light emitting areas EA1, EA2, and EA3 may be spaced apart from each other.

In addition, the material forming the cathode auxiliary electrode AX may be formed not only on the cathode electrode CE, but also on the electrode pattern CEP. The material forming the cathode auxiliary electrode AX positioned on the cathode electrode CE and the material forming the cathode auxiliary electrode AX positioned on the electrode pattern CEP may be spaced apart from each other. The material forming the cathode auxiliary electrode AX temporarily formed on the first bank layer BN1 may be referred to as an auxiliary electrode pattern AXP.

In such a process, the material forming the cathode auxiliary electrode AX may cover the first tip tip1 of the first upper conductive layer BN31 and the second tip tip2 of the second upper conductive layer BN32, and may be in contact with the first tip tip1 of the first upper conductive layer BN31.

Next, an element inorganic layer IO is formed on the cathode auxiliary electrode AX. The element inorganic layer IO may entirely cover the cathode auxiliary electrode AX with a uniform thickness along the profile of the lower structure.

In such a process, the process of forming the element inorganic layer IO may be formed through a film forming process (e.g., a deposition process) that forms at least one of the above-mentioned inorganic materials.

Next, a photoresist PR2 is formed in the first light emitting area EA1 and a portion overlapping a periphery of the first light emitting area EA1, and a fourth etching process is performed using the photoresist PR2 as a mask. In an embodiment, for example, in the fourth etching process, a dry etching process and a wet etching process may be alternately performed.

In this process, the material forming the first light emitting layer EL1, the material forming the cathode electrode CE, the material forming the cathode auxiliary electrode AX, and the material forming the element inorganic layer IO that do not overlap the photoresist PR2 may all be removed. Accordingly, the anode electrode AE overlapping the second light emitting area EA2 and the anode electrode AE overlapping the third light emitting area EA3 may be exposed again, and the element inorganic layer IO may be formed in the form of a first element inorganic layer IO1.

In this process, the first element inorganic layer IO1 may be spaced apart from the first bank layer BN1 in the third direction DR3. This may be caused by the organic pattern ELP, the electrode pattern CEP, and the auxiliary electrode pattern AXP being removed through the fourth etching process.

In this way, the first light emitting element ED1 and the first element inorganic layer IO1 positioned in the portion overlapping the first light emitting area EA1 may be formed.

Next, a second light emitting layer EL2, a cathode electrode CE, a cathode auxiliary electrode AX, and an element inorganic layer IO are formed on the anode electrode AE overlapping the second light emitting area EA2 by repeating the above-described processes. Through this process, the second light emitting element ED2 and the second element inorganic layer IO2 overlapping the second light emitting area EA2 may be formed.

In addition, a third light emitting layer EL3, a cathode electrode CE, a cathode auxiliary electrode AX, and an element inorganic layer IO are formed on the anode electrode AE overlapping the third light emitting area EA3 by repeating the above-described processes again. Through this process, the third light emitting element ED3 and the third element inorganic layer IO3 overlapping the third light emitting area EA3 may be formed.

As a result, the display element layer EML illustrated in FIG. 5 may be formed.

Referring back to FIGS. 1 to 21, as the display device 10 according to an embodiment includes the first tip tip1 of the first upper conductive layer BN31 and the second tip tip2 of the second upper conductive layer BN32, the first light emitting element ED1, the second light emitting element ED2, and the third light emitting element ED3 spaced apart from each other may be formed in the portions overlapping the first to third light emitting areas EA1, EA2, and EA3 without the separate fine metal mask. Accordingly, the display device 10 according to an embodiment may have ease of fabrication.

In addition, the display device 10 according to an embodiment may efficiently provide a high-resolution display device by disposing the bank structure BN in a portion overlapping a light emitting area EA and forming the first light emitting element ED1, the second light emitting element ED2, and the third light emitting element ED3 on the bank structure BN.

In addition, the display device 10 according to an embodiment may increase the contact area between the cathode electrode CE and/or the cathode auxiliary electrode AX and the bank structure BN by forming the first tip tip1 and the second tip tip2 having the regular tapered shape without using a separate mask. Accordingly, the electrical resistance of the display device 10 according to an embodiment may be reduced.

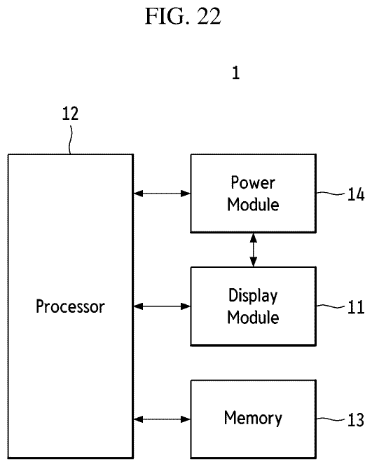

FIG. 22 is a block diagram of an electronic device according to an embodiment.

Referring to FIG. 22 in addition to FIGS. 1 to 21, the display device 10 according to an embodiment may be applied to various electronic devices 1. The electronic device 1 according to an embodiment may include the display device 10 described above, and may further include a module or device having additional functions in addition to the display device 10.

The electronic device 1 according to an embodiment may include a display module 11, a processor 12, a memory 13, and a power module 14.

The display module 11 may include a display device corresponding to one of embodiments described above.

The processor 12 may include at least one selected from a central processing unit (CPU), an application processor (AP), a graphic processing unit (GPU), a communication processor (CP), an image signal processor (ISP), and a controller.

Data information for an operation of the processor 12 or the display module 11 may be stored in the memory 13. When the processor 12 executes an application stored in the memory 13, image data signals and/or input control signals may be transmitted to the display module 11, and the display module 11 may process the provided signals and output image information through a display screen.

The power module 14 may include a power supply module, such as a power adapter or a battery device, and a power conversion module that converts power supplied by the power supply module to generate power for an operation of the electronic device 1.

At least one of the components of the electronic device 1 described above may be included in the display device according to the above-described embodiments. In addition, some of the individual modules functionally included within one module may be included within the display device, while others may be provided separately from the display device. In an embodiment, for example, the electronic device 1 includes the display module 11, and the processor 12, the memory 13, and the power module 14 may be provided in the form of other devices within the electronic device 1 other than the display device.

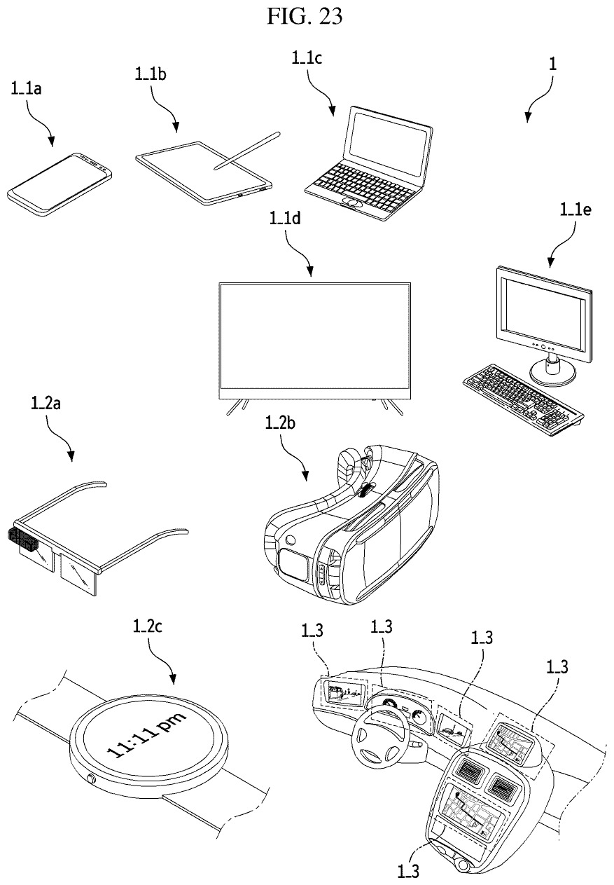

FIG. 23 illustrates schematic diagrams of electronic devices according to various embodiments.

Referring to FIG. 23, various electronic devices 1 to which the display device 10 according to the embodiments is applied may include not only an image display electronic device such as a smart phone 1_1a, a tablet personal computer (PC) 1_1b, a laptop computer 1_1c, a television (TV) 1_1d, and a desk monitor 1_1e, but also a wearable electronic device including a display module such as a smart glasses 1_2a, a head mounted display 1_2b, a smart watch 1_2c, and the like, and a vehicle electronic device 1_3 including a display module such as a center information display (CID), a room mirror display, etc., disposed on a vehicle's instrument panel, center fascia, or dashboard.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate including a light emitting area and a non-light emitting area;
a bank structure positioned on the light emitting area of the substrate, wherein the bank structure includes a first bank layer, a second bank layer, and a third bank layer which define an overhang structure; and
a light emitting element positioned on the bank structure and including an anode electrode, a light emitting layer, and a cathode electrode,
wherein the third bank layer includes:
a first upper conductive layer positioned on the second bank layer and including a first tip protruding further than a side surface of the second bank layer; and
a second upper conductive layer positioned on the first upper conductive layer and including a second tip overlapping the first tip, and
an undercut is defined between the first tip and the second tip.

2. The display device of claim 1, wherein the first tip includes:
a first surface facing the second bank layer;
a second surface opposite to the first surface; and
a first inclined surface connecting the first surface and the second surface, and
a first inclined angle formed by the first surface and the first inclined surface is an acute angle.

3. The display device of claim 2, wherein the second tip includes:
a third surface facing the first upper conductive layer;
a fourth surface opposite to the third surface; and
a second inclined surface connecting the third surface and the fourth surface,
a second inclined angle formed by the third surface and the second inclined surface is an acute angle, and
the second inclined angle is greater than the first inclined angle.

4. The display device of claim 3, wherein an undercut is defined between the first inclined surface and the second tip, and
the cathode electrode is in contact with and covers the first tip and the second tip.

5. The display device of claim 1, wherein the second bank layer, the first upper conductive layer, and the second upper conductive layer include different metal materials from each other.

6. The display device of claim 5, wherein the first upper conductive layer includes a transparent conductive oxide including tin, and
a content of tin in the first upper conductive layer is about 18% or more and about 30% or less.

7. The display device of claim 6, wherein the second bank layer includes aluminum, and
the second upper conductive layer includes titanium.

8. The display device of claim 1, further comprising:
a first element insulating layer positioned between the bank structure and the anode electrode; and
a second element insulating layer covering an edge of the anode electrode and in contact with the first element insulating layer, wherein a light emitting opening is defined in the second element insulating layer,
wherein the first element insulating layer and the second element insulating layer overlap the first tip and the second tip.

9. The display device of claim 8, wherein the light emitting layer entirely covers the second element insulating layer,
the light emitting layer overlaps the first tip and the second tip in a direction perpendicular to the substrate, and
the light emitting layer is not in contact with the first tip of the first upper conductive layer.

10. The display device of claim 8, wherein in a plan view, the third bank layer has a shape of a conductive pattern positioned to surround the light emitting opening.

11. The display device of claim 1, wherein the third bank layer further includes:
a third upper conductive layer positioned on the second upper conductive layer and including a third tip overlapping the first tip and the second tip; and
a fourth upper conductive layer positioned on the third upper conductive layer and including a fourth tip overlapping the first tip, the second tip, and the third tip,
the first upper conductive layer and the third upper conductive layer comprise a same material as each other, and
the second upper conductive layer and the fourth upper conductive layer comprise a same material as each other.

12. A method for fabricating a display device, the method comprising:
forming a first bank layer, a second bank layer, and a third bank layer of a bank structure on a substrate;
forming a first tip and a second tip of the third bank layer by performing different etching processes, respectively; and
forming a light emitting element and an element inorganic layer on the bank structure.

13. The method of claim 12, wherein the third bank layer includes a first upper conductive layer and a second upper conductive layer including different materials from each other,
the first upper conductive layer includes a transparent conductive oxide including tin, and the first upper conductive layer has a first tip which protrudes further than a side surface of the second bank layer formed by performing a wet etching process.

14. The method of claim 13, wherein the second upper conductive layer includes titanium, and
the second upper conductive layer has a second tip which protrudes further than the side surface of the second bank layer formed by performing a dry etching process.

15. An electronic device comprising:
a display device including a substrate including a light emitting area and a non-light emitting area; and
at least one selected from a processor, a memory, and a power module connected to the display device,
wherein the display device includes:
a bank structure positioned on the light emitting area of the substrate, wherein the bank structure includes a first bank layer, a second bank layer, and a third bank layer which define an overhang structure; and
a light emitting element positioned on the bank structure and including an anode electrode, a light emitting layer, and a cathode electrode,
the third bank layer includes:
a first upper conductive layer positioned on the second bank layer and including a first tip protruding further than a side surface of the second bank layer; and
a second upper conductive layer positioned on the first upper conductive layer and including a second tip overlapping the first tip, and
an undercut is defined between the first tip and the second tip.

16. The electronic device of claim 15, wherein the first tip includes:
a first surface facing the second bank layer;
a second surface opposite to the first surface; and
a first inclined surface connecting the first surface and the second surface, and
a first inclined angle formed by the first surface and the first inclined surface is an acute angle.

17. The electronic device of claim 16, wherein the second tip includes:
a third surface facing the first upper conductive layer;
a fourth surface opposite to the third surface; and
a second inclined surface connecting the third surface and the fourth surface,
a second inclined angle formed by the third surface and the second inclined surface is an acute angle, and
the second inclined angle is greater than the first inclined angle.

18. The electronic device of claim 17, wherein an undercut is formed between the first inclined surface and the second tip, and
the cathode electrode is in contact with and covers the first tip and the second tip.

19. The electronic device of claim 15, wherein the first upper conductive layer includes a transparent conductive oxide including tin, and
a content of tin in the first upper conductive layer is about 18% or more and about 30% or less.

20. The electronic device of claim 19, wherein the second bank layer includes aluminum, and
the second upper conductive layer includes titanium.
